(19) United States
(12) Patent Application Publication
(10) Pub. No.: US 2026/0293747 A1
(43) Pub. Date: Sep. 24, 2026

(54) SEMICONDUCTOR DEVICE COMPRISING STACKED SEMICONDUCTOR CHIPS

(71) Applicant: Samsung Electronics Co., Ltd., Suwon-si (KR)

(72) Inventors: Sang Cheon Park, Suwon-si (KR); Un-Byoung Kang, Suwon-si (KR); Yongbum Kwon, Suwon-si (KR); Junwoo Myung, Suwon-si (KR); Jumyong Park, Suwon-si (KR); Teak Hoon Lee, Suwon-si (KR)

(21) Appl. No.: 19/355,643

(22) Filed: Oct. 10, 2025

(30) Foreign Application Priority Data
Mar. 18, 2025 (KR) 10-2025-0034842

(51) Int. Cl. H01L 23/31; H01L 21/56; H01L 23/00; H01L 25/18; H10B 80/00; H10D 80/30

(52) U.S. Cl. CPC H10W 74/111; H10B 80/00; H10D 80/30; H10W 74/014; H10W 90/00; H10W 74/15; H10W 90/297; H10W 90/722; H10W 90/724; H10W 90/732; H10W 90/792

(57) ABSTRACT

An example semiconductor device includes a first semiconductor chip including a first substrate and a first through electrode penetrating the first substrate, a plurality of second semiconductor chips that include a second substrate that is disposed in a first direction intersecting a surface of the first semiconductor chip and a second through electrode penetrating the second substrate, and are sequentially stacked in the first direction, and a molding layer surrounding the first semiconductor chip and the plurality of second semiconductor chips. A thickness of a first part of the molding layer that is in contact with a side of the first semiconductor chip is different from a thickness of a second part of the molding layer that is in contact with a side of the second semiconductor chip.

### CROSS-REFERENCE TO RELATED APPLICATION

This application claims the benefit of Korean Patent Application No. 10-2025-0034842, filed on Mar. 18, 2025, in the Korean Intellectual Property Office, the disclosure of which is incorporated herein by reference in its entirety.

### BACKGROUND

As electronic products become smaller, their capacity becomes larger, and their performance becomes higher, higher integration and higher speed of semiconductor packages are desired. For this, a semiconductor device including stacked semiconductor chips and a semiconductor chip to be stacked within a semiconductor device are being developed. However, the high pressure used in the process of vertically stacking semiconductor chips may cause defects in the chips located at the bottom.

### SUMMARY

The present disclosure relates to a semiconductor device with minimal defects and improved reliability, and a method for manufacturing a semiconductor device with improved yield.

The technical tasks to be achieved by the present example implementations are not limited to the technical tasks described above, and other technical tasks may be inferred from the following example implementations by those skilled in the art.

In some implementations, a semiconductor device includes a first semiconductor chip including a first substrate and a first through electrode penetrating the first substrate, a plurality of second semiconductor chips that include a second substrate that is disposed in a first direction intersecting a surface of the first semiconductor chip and a second through electrode penetrating the second substrate, and are sequentially stacked in the first direction, and a molding layer surrounding the first semiconductor chip and the plurality of second semiconductor chips. The thickness of a first part of the molding layer that is in contact with a side of the first semiconductor chip is different from the thickness of a second part of the molding layer that is in contact with a side of the second semiconductor chip.

In some implementations, a semiconductor device includes a package substrate and a memory chip structure including a plurality of chips mounted on the package substrate. The plurality of chips include a buffer chip including a first substrate and a first through electrode penetrating the first substrate, and located at a bottom among the plurality of chips, a plurality of memory chips including a second substrate disposed along a first direction intersecting a surface of the buffer chip and a second through electrode penetrating the second substrate, and a plurality of memory chips are sequentially stacked in the first direction, and a first molding layer surrounding the buffer chip. The length of outer circumference of the first molding layer is longer than the length of outer circumference of the buffer chip.

In some implementations, a semiconductor device includes a buffer chip and a plurality of memory chips that are sequentially stacked in a first direction intersecting a surface of the buffer chip. The buffer chip includes a first substrate having an inactive surface, a first through electrode penetrating the first substrate, a first interconnection structure disposed on a lower surface of the first substrate, and a first connecting bump connected with the first interconnection structure, and each of the plurality of memory chips includes a second substrate having a width smaller than the first substrate and having an active surface facing the inactive surface of the first substrate, a second through electrode penetrating the second substrate, a second interconnection structure disposed on a lower surface of the second substrate, and a second connecting bump connected with the second interconnection structure. The semiconductor device further includes an under-filling layer interposing between each of the plurality of memory chips to surround the second connecting bump and a molding layer surrounding the buffer chip, the plurality of memory chips and the under-filling layer and including a bottom surface located to be coplanar with a lower surface of the buffer chip, and the thickness of a first part of the molding layer surrounding the first substrate is thinner than the thickness of a second part of the molding layer surrounding the second substrate.

In some implementations, a method of manufacturing a semiconductor device includes preparing a semiconductor wafer including a plurality of first semiconductor chips that are spaced apart by scribe lanes, forming a plurality of first connecting bumps on front sides of the plurality of first semiconductor chips, attaching the semiconductor wafer to a carrier wafer in order for the plurality of first connecting bumps to face a carrier substrate, dicing the semiconductor wafer along the scribe lanes, forming a plurality of chip structures by stacking each of a plurality of second semiconductor chips on the plurality of first semiconductor chips, forming a molding layer surrounding the plurality of chip structures, in order for the plurality of first connecting bumps not to face tape, attaching the plurality of chip structures to the tape, and dicing the molding layer in order for the plurality of chip structures to be separated from each other, and a side of the first semiconductor chip is exposed when the semiconductor wafer is diced along the scribe lanes.

In some implementations, a method of manufacturing a semiconductor device includes forming the molding layer in which the thickness of a first part of the molding layer that is in contact with a side of the first semiconductor chip is different from the thickness of a second part of the molding layer that is in contact with a side of the second semiconductor chip.

In some implementations, a method of manufacturing a semiconductor device includes forming the plurality of chip structures by stacking each of the plurality of second semiconductor chips on the plurality of first semiconductor chips, wherein the width of the plurality of second semiconductor chips is smaller than the width of the plurality of first semiconductor chips.

In some implementations, a method of manufacturing a semiconductor device includes that in dicing the semiconductor wafer along the scribe lanes, the scribe lanes have a first gap, and in dicing the molding layer, the molding layer is diced along a dicing line having a second gap smaller than the first gap.

a method of manufacturing a semiconductor device includes that in dicing the molding layer, sides of the plurality of first semiconductor chips are misaligned with a side of the molding layer.

In some implementations, a method of manufacturing a semiconductor device includes forming the plurality of chip structures by stacking each of the plurality of second semiconductor chips on the plurality of first semiconductor chips, and in the forming the plurality of chip structures, the plurality of first semiconductor chips and the plurality of second semiconductor chips are connected by second connecting bumps.

### BRIEF DESCRIPTION OF THE DRAWINGS

These and/or other aspects, features, and advantages of the present disclosure will become apparent and more readily appreciated from the following description of example implementations, taken in conjunction with the accompanying drawings.

FIG. 1 is a schematic plan view illustrating an example of a semiconductor device.

FIG. 2 is a drawing illustrating an example of a cross-section taken along line A1-Al′ of FIG. 1.

FIG. 3 is an example enlarged view of the portion indicated as “CX1” in FIG. 2.

FIG. 4 is an example enlarged view of the portion marked “CX1” in FIG. 2.

FIG. 5 is a drawing illustrating an example of a semiconductor device and an example of a cross-section taken along line A1-A1′ of FIG. 1.

FIG. 6 is a schematic plan view illustrating an example of a semiconductor device.

FIG. 7 is a drawing illustrating an example of a cross-section taken along line A2-A2′ of FIG. 6.

FIG. 8 is a schematic plan view illustrating an example of a semiconductor device.

FIG. 9 is a schematic plan view illustrating an example of a semiconductor device.

FIG. 10 is a drawing illustrating an example of a cross-section taken along line A3-A3′ OF FIG. 9.

FIG. 11 is a drawing illustrating an example of a semiconductor device and an example of a cross-section taken along line A3-A3′ of FIG. 9.

FIG. 12 is an example enlarged view of the portion marked “CX2” in FIG. 11.

FIG. 13 is a cross-sectional view illustrating an example of a semiconductor package.

FIGS. 14A, 14B, 14C, 14D, 14E, 14F, 14G, 14H, 14I, 14J, 14K, 14L, 14M, and 14N are cross-sectional views illustrating a process sequence for explaining an example of a method of manufacturing a semiconductor device.

FIG. 15 is a cross-sectional view illustrating an example of a method for manufacturing a semiconductor device.

FIGS. 16A, 16B, 16C, 16D, and 16E are cross-sectional views illustrating a process sequence for explaining an example of a method of manufacturing a semiconductor device.

FIGS. 17A, 17B, 17C, and 17D are cross-sectional views illustrating a process sequence for explaining an example of a method of manufacturing a semiconductor device.

### DETAILED DESCRIPTION

Hereinafter, example implementations of the present disclosure will be described in detail with reference to the attached drawings. Identical reference numerals are used for identical elements on the drawings, and repetitive descriptions of identical elements on the drawing are omitted.

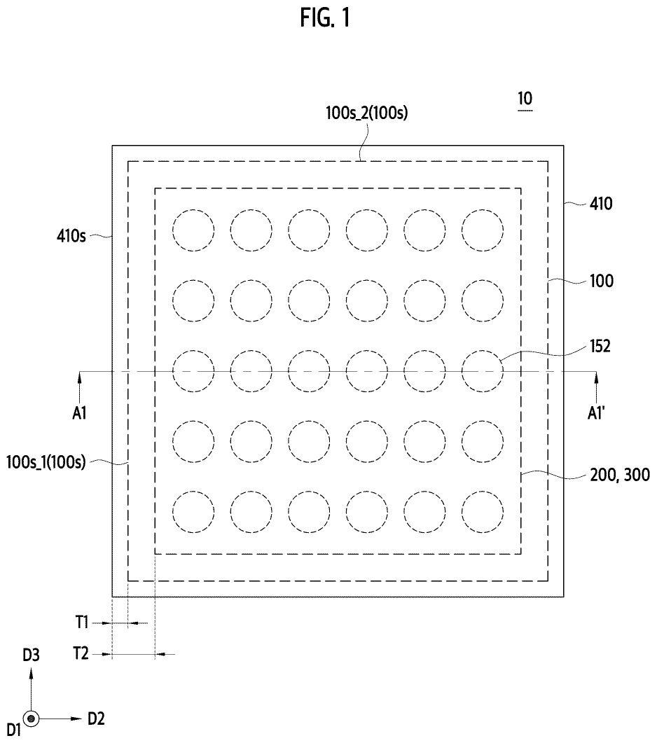

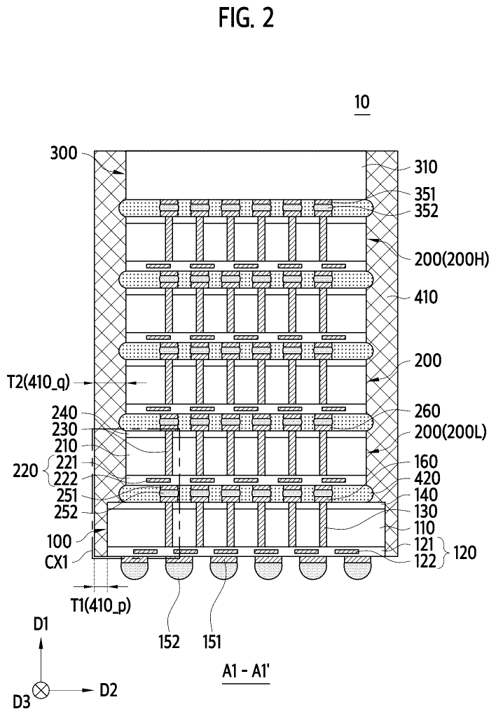

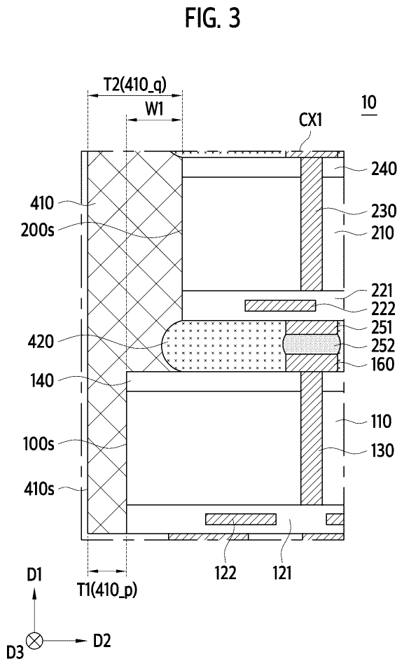

FIG. 1 is a schematic plan view illustrating an example of a semiconductor device. FIG. 2 is a drawing illustrating an example of a cross-section taken along line A1-A1′ of FIG. 1. FIG. 3 is an example enlarged view of the portion indicated as “CX1” in FIG. 2.

In some implementations, a semiconductor device 10 may include a first semiconductor chip 100, a second semiconductor chip 200, a dummy chip 300, a molding layer 410 and an under-filling layer 420.

FIG. 1 illustrates that the semiconductor device 10 includes one first semiconductor chip 100 and four second semiconductor chips 200, but the present disclosure is not limited thereto. For example, the semiconductor device 10 may include two or more second semiconductor chips 200. In some implementations, the semiconductor device 10 may contain a multiple of 4 second semiconductor chips 200. The plurality of second semiconductor chips 200 may be sequentially stacked along the first direction D1 on the first semiconductor chip 100. Each of the first semiconductor chip 100 and the plurality of second semiconductor chips 200 may be sequentially stacked with the active surfaces facing downward. Here, the term “downward” refers to the direction in which the first semiconductor chip 100 is located relative to the second semiconductor chip 200.

In some implementations, the first semiconductor chip 100 may include a first substrate 110, a first interconnection structure 120, a first through electrode 130, a first back side protection layer 140, a first connecting pad 151, a first connecting bump 152 and a first back side pad 160. The first interconnection structure 120 may be arranged on the lower surface of the first substrate 110, and the first back side protection layer 140 may be placed on the upper surface of the first substrate 110. In some implementations, a front side and a back side refer to the sides located on the active surface side and the inactive surface side, and an upper surface and a lower surface refer to the surfaces located at the upper and lower sides along the first direction D1 in the drawing.

In some implementations, the first substrate 110 may have a rectangular shape in a horizontal view along the first direction D1. In the horizontal view, the outline of the first substrate 110 may match the outline of the first semiconductor chip 100. However, the first substrate 110 is not limited thereto, and according to an example implementation, another element of the first semiconductor chip 100 may be added and positioned on the side of the first substrate 110.

In some implementations, the first back side protection layer 140 may extend along the upper surface of the first substrate 110. The side of the first back side protection layer 140 may be aligned with the side of the first substrate 110. The first back side protection layer 140 may be made of, for example, an insulating polymer.

In some implementations, the first back side pad 160 may be placed on the first back side protection layer 140. The first back side pad 160 may provide a terminal for connection to the second semiconductor chips 200 stacked on the first semiconductor chip 100. For example, the first back side pad 160 may contain a metal material such as copper or tungsten.

In some implementations, the first back side pad 160 may be composed of a barrier film for wiring and a metal layer for wiring. The barrier film for wiring may be made of metal, metal nitride, or alloy. The metal layer for wiring may include at least one metal selected from W, Al, Ti, Ta, Ru, Mn and Cu.

In some implementations, the first through electrode 130 may electrically connect the first interconnection structure 120 and the first back side pad 160 by penetrating at least a portion of the first substrate 110 in the first direction D1. For example, a portion of a first interconnection 122 of the first interconnection structure 120 may be connected to the lower portion of the first through electrode 130, and the first back side pad 160 may be connected to the upper portion of the first through electrode 130.

In some implementations, at least a portion of the first through electrode 130 may be columnar in shape. The first through electrode 130 may be formed of a barrier film formed on a columnar surface and a buried conductive layer filling the inside of the barrier film. The barrier film may include at least one material selected from Ti, TiN, Ta, TaN, Ru, Co, Mn, WN, Ni and NiB, and the buried conductive layer may include at least one material selected from Cu alloys such as Cu, CuSn, CuMg, CuNi, CuZn, CuPd, CuAu, CuRe and CuW, W, W alloy, Ni, Ru and Co. An insulating film may be interposed between the first substrate 110 and the first through electrode 130. The insulating film may be formed of an oxide film, a nitride film, a carbide film, a polymer, or a combination thereof.

In some implementations, the first interconnection structure 120 may be arranged on the lower surface of the first substrate 110. The first interconnection structure 120 may include a first insulation layer 121 and the first interconnection 122. In some implementations, the first interconnection 122 may include a plurality of first interconnection patterns and a plurality of first interconnection vias. Here, the plurality of first interconnection vias may be connected to the upper surface and/or lower surface of a plurality of first interconnection patterns. In some implementations, the plurality of first interconnection patterns may be arranged at different vertical levels along the first direction D1. The plurality of first interconnection vias may connect first interconnection patterns arranged at different vertical levels. The plurality of first interconnection patterns and the plurality of first interconnection vias may electrically connect a plurality of first through electrodes 130 and a plurality of first connecting pads 151. The first insulation layer 121 may surround the first interconnection 122. The side of the first insulation layer 121 may be aligned with the side of the first substrate 110.

In some implementations, the first interconnection 122 may be composed of a barrier film for wiring and a metal layer for wiring. The barrier film for wiring may be made of metal, metal nitride, or alloy. The metal layer for wiring may include at least one metal selected from W, Al, Ti, Ta, Ru, Mn and Cu. The first insulation layer 121 may be composed of silicon oxide, silicon nitride, silicon oxynitride, an insulating material having a lower dielectric constant than silicon oxide, or a combination thereof. In some implementations, the first insulation layer 121 may be made of a tetraethyl orthosilicate (TEOS) film or an ultra-low K (ULK) film having an ultra-low dielectric constant K of about 2.2 to 2.4. The ULK film may include a SiOC film or a SiCOH film.

In some implementations, the first connecting pad 151 may be positioned on the lower surface of the first interconnection structure 120. The plurality of first connecting pads 151 may be provided, and the plurality of first connecting pads 151 may be spaced apart in the second direction D2 and/or the third direction D3 on the lower surface of the first interconnection structure 120. In the present disclosure, the second direction D2 may be defined as a direction that intersects the first direction D1 and is parallel to the upper surfaces of the first substrate 110 and a second substrate 210. The third direction D3 may be defined as the direction intersecting the first direction D1 and the second direction D2. In the present disclosure, to facilitate understanding, the first direction D1 is referred to as the vertical direction, and the second direction D2 and the third direction D3 are referred to as the horizontal directions.

In some implementations, a plurality of first connecting bumps 152 may be provided, and each of the plurality of first connecting bumps 152 may be attached to the first connecting pad 151. The first connecting bump 152 may provide a terminal for connection with another semiconductor device when the first semiconductor chip 100 is mounted on another semiconductor device. For example, the “another semiconductor device” may be an interposer, but it is not limited thereto.

In some implementations, the first connecting pad 151 may be composed of a barrier film for wiring and a metal layer for wiring. The barrier film for wiring may be made of metal, metal nitride, or alloy. The metal layer for wiring may include at least one metal selected from W, Al, Ti, Ta, Ru, Mn and Cu. The first connecting bump 152 may be a solder ball or a bump.

In some implementations, the second semiconductor chip 200 may include the second substrate 210, a second interconnection structure 220, a second through electrode 230, a second back side protection layer 240, a second connecting pad 251, a second connecting bump 252 and a second back side pad 260. The second interconnection structure 220 may be arranged on the lower surface of the second substrate 210, and the second back side protection layer 240 may be placed on the upper surface of the second substrate 210.

In some implementations, the second substrate 210 may have a rectangular shape in a horizontal view along the first direction D1. In the horizontal view, the outline of the second substrate 210 may match the outline of the second semiconductor chip 200. In some implementations, another element of the second semiconductor chip 200 may be added and positioned on the side of the second substrate 210.

In some implementations, the second back side protection layer 240 may extend along the upper surface of the second substrate 210. The side of the second back side protection layer 240 may be aligned with the side of the second substrate 210. The material included in the second back side protection layer 240 may be identical or substantially identical to the material included in the first back side protection layer 140.

In some implementations, the second back side pad 260 may be placed on the second back side protection layer 240. The second back side pad 260 may provide a terminal for connecting another second semiconductor chip 200 stacked on the second semiconductor chip 200. The material included in the second back side pad 260 may be identical or substantially identical to the material included in the first back side pad 160.

In some implementations, the second through electrode 230 may electrically connect the second interconnection structure 220 and the second back side pad 260 by penetrating at least a portion of the second substrate 210 in the first direction D1. For example, a portion of a second interconnection 222 of the second interconnection structure 220 may be connected to the lower portion of the second through electrode 230, and the second back side pad 260 may be connected to the upper portion of the second through electrode 230. The material contained in the second through electrode 230 may be identical or substantially identical to the material contained in the first through electrode 130.

In some implementations, the second interconnection structure 220 may be disposed on the lower surface of the second substrate 210. The second interconnection structure 220 may include a second insulation layer 221 and the second interconnection 222. In some implementations, the second interconnection 222 may include a plurality of second interconnection patterns and a plurality of second interconnection vias. Here, the plurality of second interconnection vias may be connected to the upper surfaces and/or lower surfaces of a plurality of second interconnection patterns. In some implementations, the plurality of second interconnection patterns may be arranged at different vertical levels along the first direction D1. The plurality of second interconnection vias may connect second interconnection patterns positioned at different vertical levels. The plurality of second interconnection patterns and the plurality of second interconnection vias may electrically connect a plurality of second through electrodes 230 and a plurality of second connecting pads 251. The second insulation layer 221 may surround the second interconnection 222. The side of the second insulation layer 221 may be aligned with the side of the second substrate 210. The material contained in the second insulation layer 221 may be identical or substantially identical to the material contained in the first insulation layer 121, and the material included in the second interconnection 222 may be identical or substantially identical to the material included in the first interconnection 122.

In some implementations, the second connecting pad 251 may be positioned on the lower surface of the second interconnection structure 220. The plurality of second connecting pads 251 may be provided, and the plurality of second connecting pads 251 may be spaced apart in the second direction D2 and/or the third direction D3 on the lower surface of the second interconnection structure 220.

In some implementations, a plurality of second connecting bumps 252 may be provided, and each of the second connecting bumps 252 may be attached to the second connecting pad 251. When the second semiconductor chip 200 is mounted on the first semiconductor chip 100 or another second semiconductor chip 200, the second connecting bump 252 may provide terminals for connecting with the first semiconductor chip 100 or another second semiconductor chip 200. The material included in the second connecting pad 251 may be identical or substantially identical to the material included in the first connecting pad 151, and the material included in the second connecting bump 252 may be identical or substantially identical to the material included in the first connecting bump 152.

In some implementations, the dummy chip 300 may be placed on the second semiconductor chip 200 located at the top along the first direction D1. The dummy chip 300 may include a supportive dummy substrate 310, a third connecting pad 351 and a third connecting bump 352. The dummy chip 300 may be arranged on the plurality of second semiconductor chips 200 and configured to radiate heat generated from the plurality of second semiconductor chips 200 to the outside. Alternatively, the dummy chip 300 may be configured to protect the plurality of second semiconductor chips 200 and the first semiconductor chip 100 from external impact. For example, the supportive dummy substrate 310 may include a semiconductor material such as silicon. In some implementations, the supportive dummy substrate 310 may be made only of semiconductor material. For example, the supportive dummy substrate 310 may be a portion of a bare wafer.

In some implementations, the third connecting pad 351 may be positioned on the lower surface of the supportive dummy substrate 310. A plurality of third connecting pads 351 may be provided, and the plurality of third connecting pads 351 may be spaced apart in the second direction D2 and/or the third direction D3 on the lower surface of the supportive dummy substrate 310.

In some implementations, a plurality of third connecting bumps 352 may be provided, and each of the plurality of third connecting bumps 352 may be attached to the third connecting pad 351. When the dummy chip 300 is mounted on the second semiconductor chip 200, the third connecting bump 352 may provide a connecting terminal. The material included in the third connecting pad 351 may be identical or substantially identical to the material included in the first connecting pad 151, and the material included in the third connecting bump 352 may be identical or substantially identical to the material included in the first connecting bump 152.

In some implementations, one of the plurality of under-filling layers 420 may be interposed between the first semiconductor chip 100 and a bottom second semiconductor chip 200L of the plurality of second semiconductor chips 200. Further, another one of the plurality of under-filling layers 420 may be interposed between the dummy chip 300 and a top second semiconductor chip 200H of the plurality of second semiconductor chips 200. Further, the remaining other under-filling layers among the plurality of under-filling layers 420 may be interposed between the second semiconductor chips 200 stacked along the first direction D1. The under-filling layer 420 interposed between the first semiconductor chip 100 and the bottom second semiconductor chip 200L may surround the second connecting pad 251 and the second connecting bump 252 of the bottom second semiconductor chip 200L, while filling the space between the first semiconductor chip 100 and the bottom second semiconductor chip 200L. The under-filling layer 420 interposed between the dummy chip 300 and the top second semiconductor chip 200H may surround the third connecting pad 351 and the third connecting bump 352 of the dummy chip 300, while filling the space between the dummy chip 300 and the top second semiconductor chip 200H. The under-filling layer 420 interposed between the plurality of second semiconductor chips 200 may surround the second connecting pad 251 and the second connecting bump 252, while filling the gap between the plurality of second semiconductor chips 200.

In some implementations, one side of the under-filling layer 420 may protrude horizontally from one side of the second semiconductor chip 200 or one side of the dummy chip 300. Here, the under-filling layer 420 may cover the entire lower surface of the second semiconductor chip 200 or the entire lower surface of the dummy chip 300.

In some implementations, the under-filling layer 420 may be formed by a capillary under-fill method. For example, the under-filling layer 420 may be composed of epoxy resin. The under-filling layer 420 may include a pillar. For example, the pillar may be made of silica. The pillar may have a size of, for example, 0.1 μm to one-digit number um or less, and may have an average size of about 0.3 to 1 μm.

In some implementations, the first substrate 110 and the second substrate 210 may contain silicon. Alternatively, the first substrate 110 and the second substrate 210 may include a semiconductor element such as Ge, or a compound semiconductor such as silicon carbide (SiC), gallium arsenide (GaAs), indium arsenide (InAs) and indium phosphide (InP). The first substrate 110 and the second substrate 210 may include a plurality of individual devices of various types on the active surface. For example, the plurality of individual devices may include a variety of microelectronic devices. For example, included may be metal-oxide-semiconductor field effect transistors (MOSFET), such as complementary metal-insulator-semiconductor (CMOS) transistors, system large scale integration (LSI) circuits, image sensors such as CMOS imaging sensors (CIS), micro-electro-mechanical systems (MEMS), active devices, and/or passive devices.

In some implementations, the first semiconductor chip 100 and the second semiconductor chip 200 may include a first semiconductor device and a second semiconductor device including the plurality of individual devices. The first semiconductor device may be placed on the active surface of the first substrate 110, and the second semiconductor device may be placed on the active surface of the second substrate 210.

In some implementations, the plurality of second semiconductor chips 200 may be dynamic random access memory (DRAM), static random access memory (SRAM), flash memory, electrically erasable and programmable read-only memory (EEPROM), phase-change random access memory (PRAM), magnetic random access memory (MRAM), or resistive random access memory (RRAM).

In some implementations, the first semiconductor chip 100 may not contain any memory cells. The first semiconductor device included in the first semiconductor chip 100 may include a serial-parallel conversion circuit, a test logic circuit such as design for test (DFT), joint test action group (JTAG) and memory builtin self-test (MBIST), and a signal interface circuit such as PHY. The second semiconductor device including the plurality of second semiconductor chips 200 may include a memory cell. For example, the first semiconductor chip 100 may be a buffer chip for controlling the plurality of second semiconductor chips 200.

In some implementations, the width of the first substrate 110 of the first semiconductor chip 100 in the horizontal direction (the second direction D2 and/or the third direction D3) may be greater than the width of the second substrate 210 of the second semiconductor chip 200 in the horizontal direction (the second direction D2 and/or the third direction D3). Here, the plurality of second semiconductor chips 200 may completely overlap the first semiconductor chip 100 from a horizontal perspective.

In some implementations, the first semiconductor chip 100 may be a buffer chip for controlling high-bandwidth-memory (HBM) DRAM, and the plurality of second semiconductor chips 200 may be memory cell chips having cells of HBM DRAM controlled by the first semiconductor chip 100. The first semiconductor chip 100 may be called a buffer chip or a master chip, and the second semiconductor chip 200 may be referred to as a memory cell chip or a slave chip. The first semiconductor chip 100 and the plurality of second semiconductor chips 200 stacked on the first semiconductor chip 100 may be collectively referred to as an HBM DRAM device or an HBM DRAM chip.

In some implementations, the molding layer 410 may surround the first semiconductor chip 100, the plurality of second semiconductor chips 200, the dummy chip 300 and the under-filling layer 420. The molding layer 410 may not contact the first connecting pad 151 and the first connecting bump 152 of the first semiconductor chip 100. The bottom surface of the molding layer 410 may be positioned in the same plane as the bottom surface of the first interconnection structure 120. For example, the molding layer 410 may be made of epoxy mold compounds (EMCs). The molding layer 410 may include a pillar. For example, the pillar may be made of silica. For example, the pillar may have a size of one-digit number um to two-digit number μm, and may have an average size of about 2 to 10 micrometers.

In some implementations, the area in contact with a side 100s of the first semiconductor chip 100 of the molding layer 410 may be defined as a first part 410_p, and the area in contact with a side 200s of the second semiconductor chip 200 of the molding layer 410 may be defined as a second part 410_q. Here, the thickness T1 of the first part 410_p and the thickness T2 of the second part 410_q may be different from each other. In some implementations, since the width of the first semiconductor chip 100 in the lateral direction (the second direction D2 and/or the third direction D3) is greater than the width of the second semiconductor chip 200 in the lateral direction (the second direction D2 and/or the third direction D3), the thickness T1 of the first part 410_p may be smaller than the thickness T2 of the second part 410_q. For example, the thickness T1 of the first part 410_p may be in the range of 30 μm to 300 μm.

In some implementations, a side 410s of the molding layer 410 may be a flat plane. In addition, the side 410s of the molding layer 410 may not be located on the same plane as a side 100s of the first semiconductor chip 100. The side 100s of the first semiconductor chip 100 may be misaligned with the side 410s of the molding layer 410. In the present disclosure, the side 100s of the first semiconductor chip 100 may be identical to the side of the first substrate 110 or the side of the first insulation layer 121.

Hereinafter, as illustrated in FIG. 1, example implementations are described from the horizontal perspective intersecting the first direction D1. In the horizontal perspective view, the distance between the two sides 410s of the molding layer 410 spaced along the second direction D2 may be greater than the width along the second direction D2 of the first semiconductor chip 100. Similarly, the distance between the two sides 410s of the molding layer 410 spaced apart in the third direction D3 may also be greater than the width of the first semiconductor chip 100 in the third direction D3. In other words, in the horizontal perspective view, the corner defining the outline of the molding layer 410 may surround the corner of the first semiconductor chip 100. Further, in the horizontal perspective view, the length of the outer perimeter of the molding layer 410 may be longer than the length of the outer perimeter of the first semiconductor chip 100.

Further, in some implementations, the thickness T1 of a part of the molding layer 410 covering a first side 100s_1 intersecting with the second direction D2 of the first semiconductor chip 100 may be equal to the thickness of a portion of the molding layer 410 covering a second side 100s_2 intersecting the first side 100s_1.

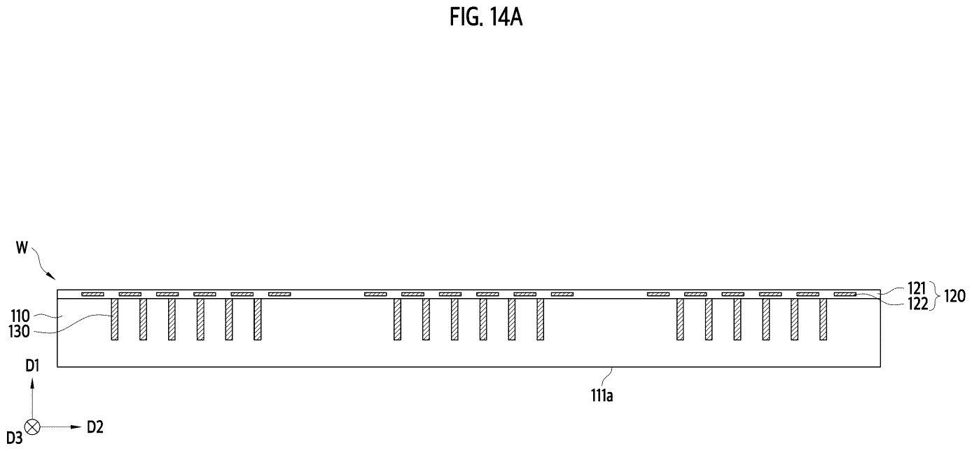

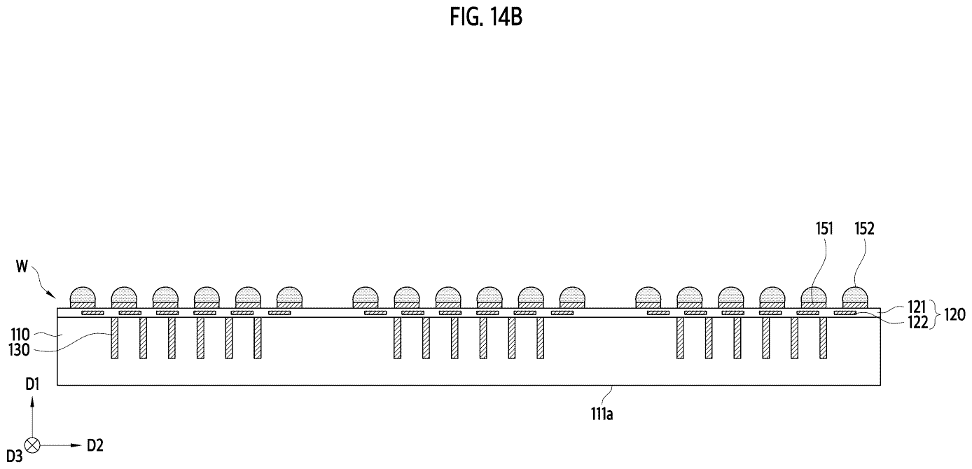

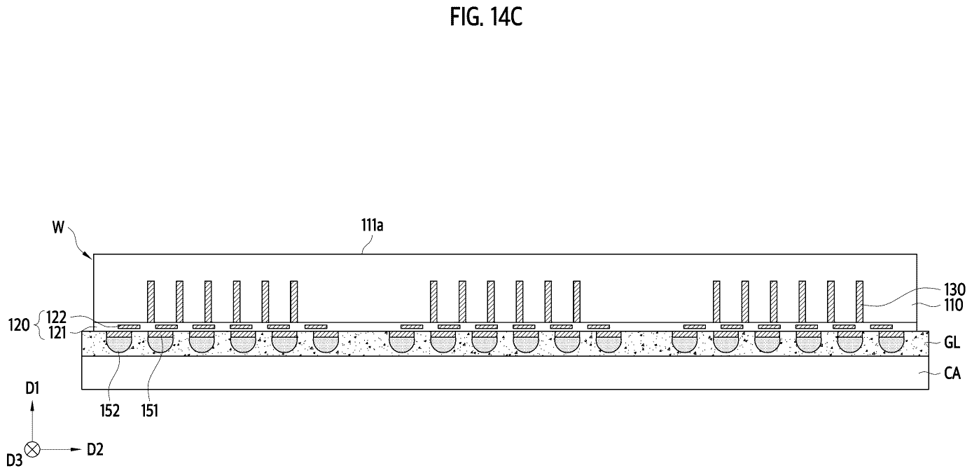

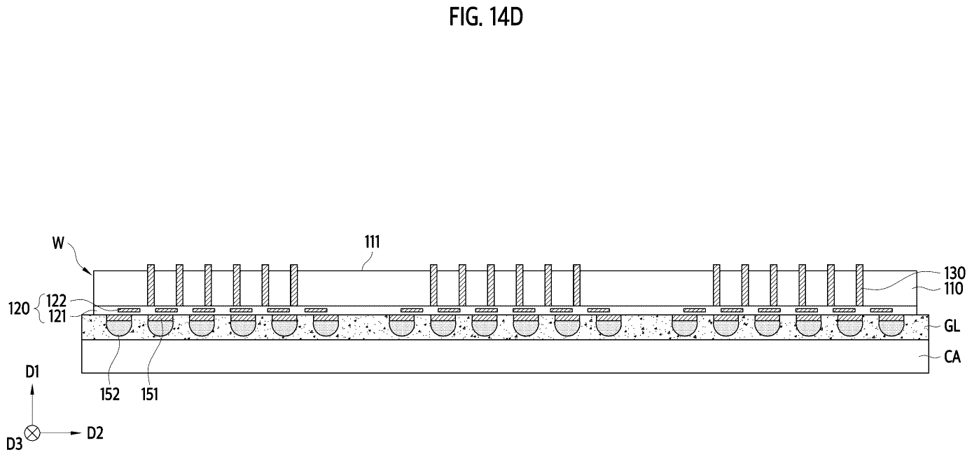

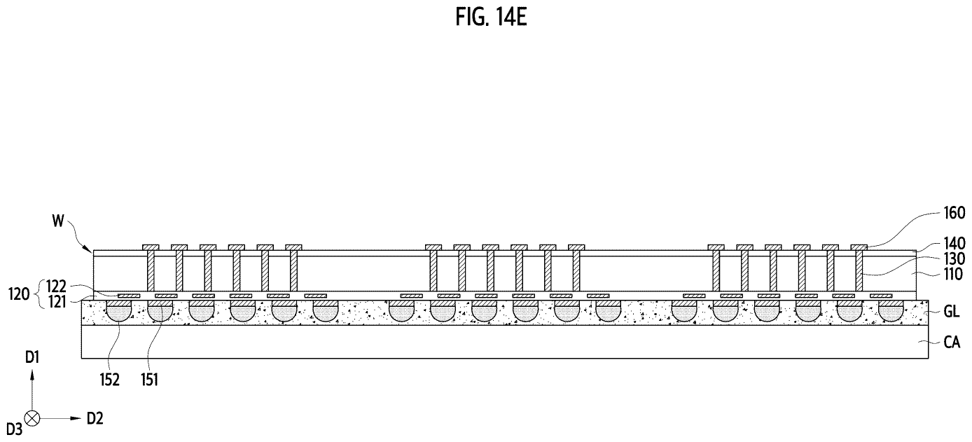

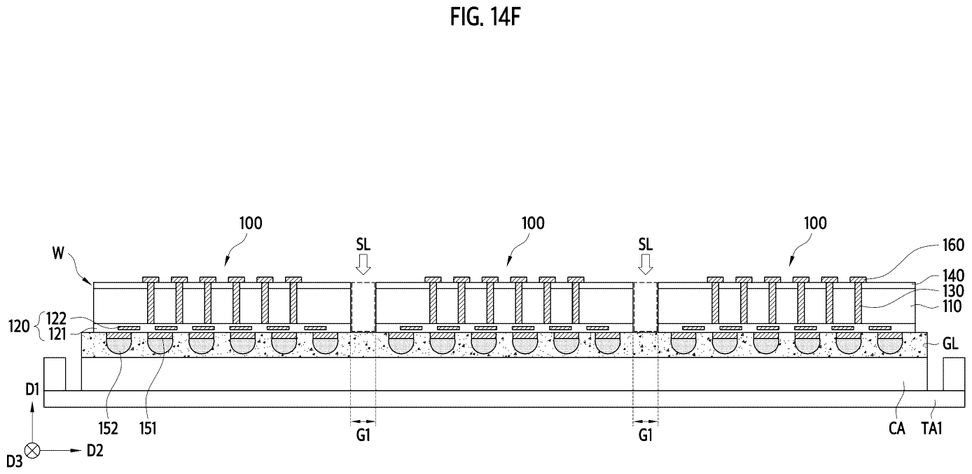

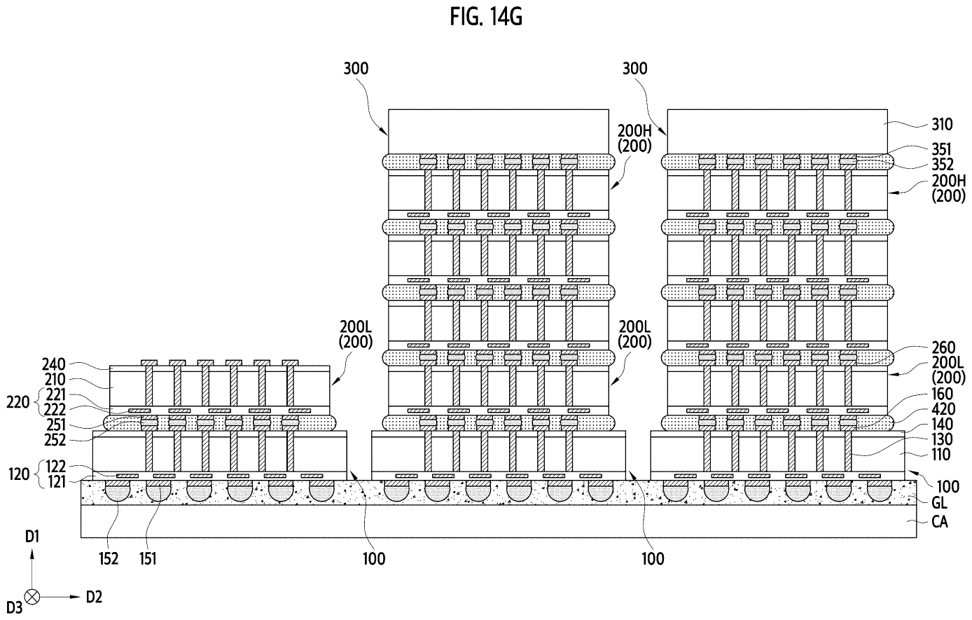

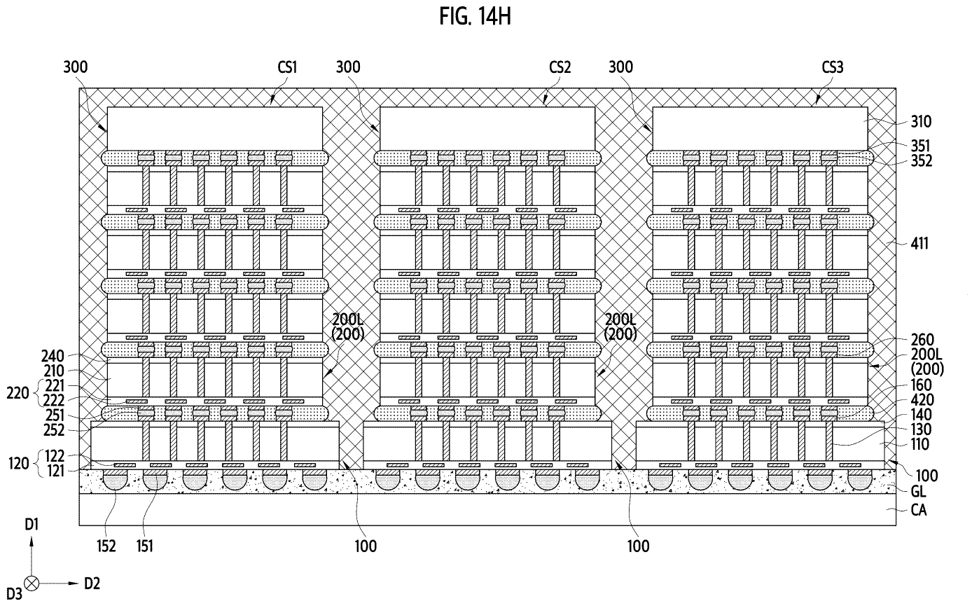

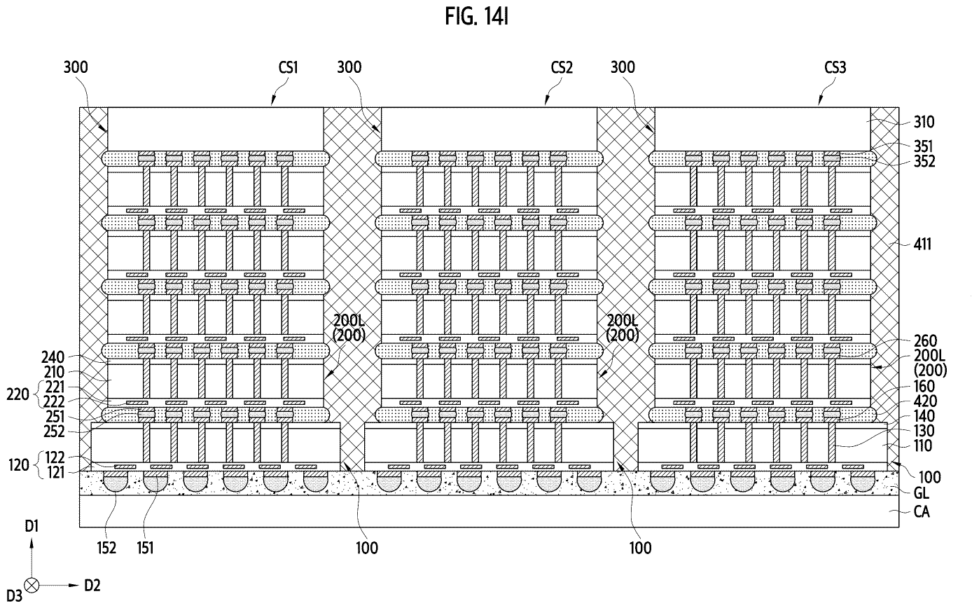

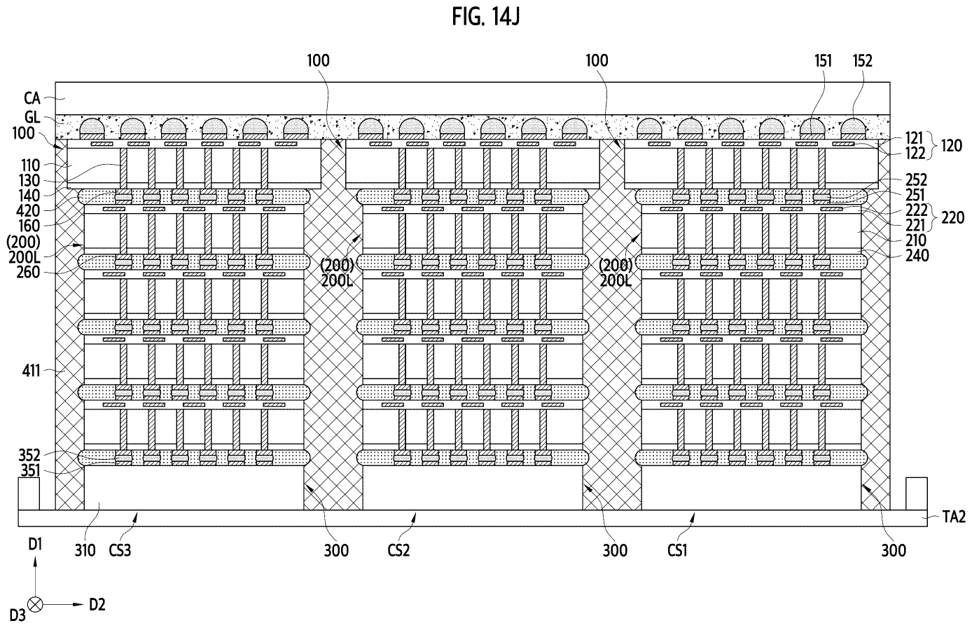

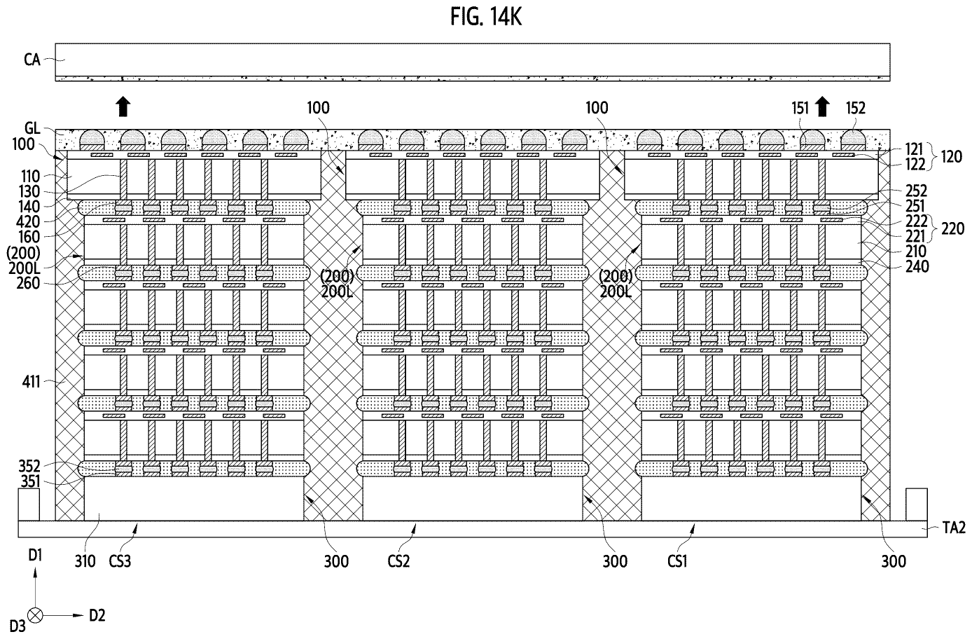

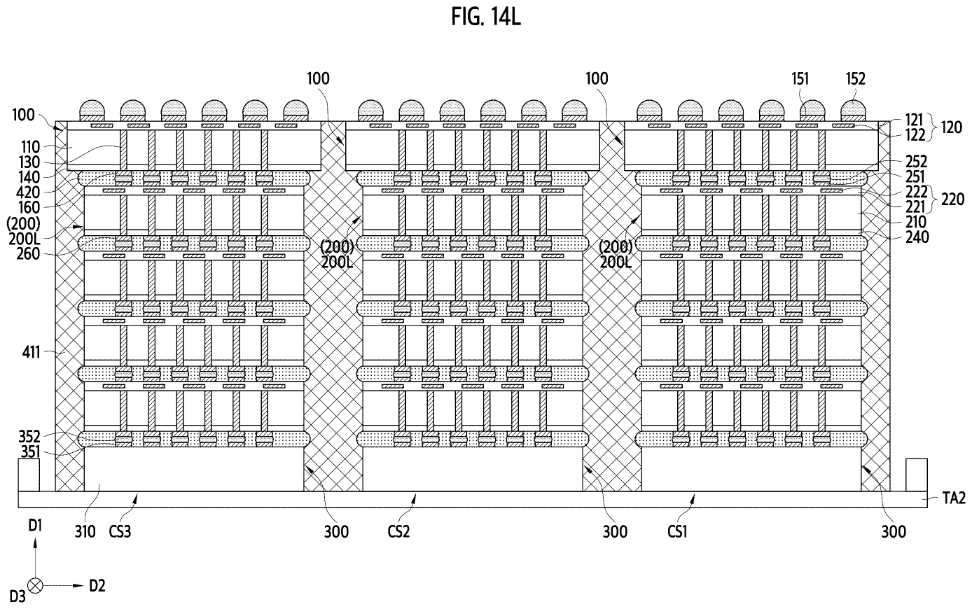

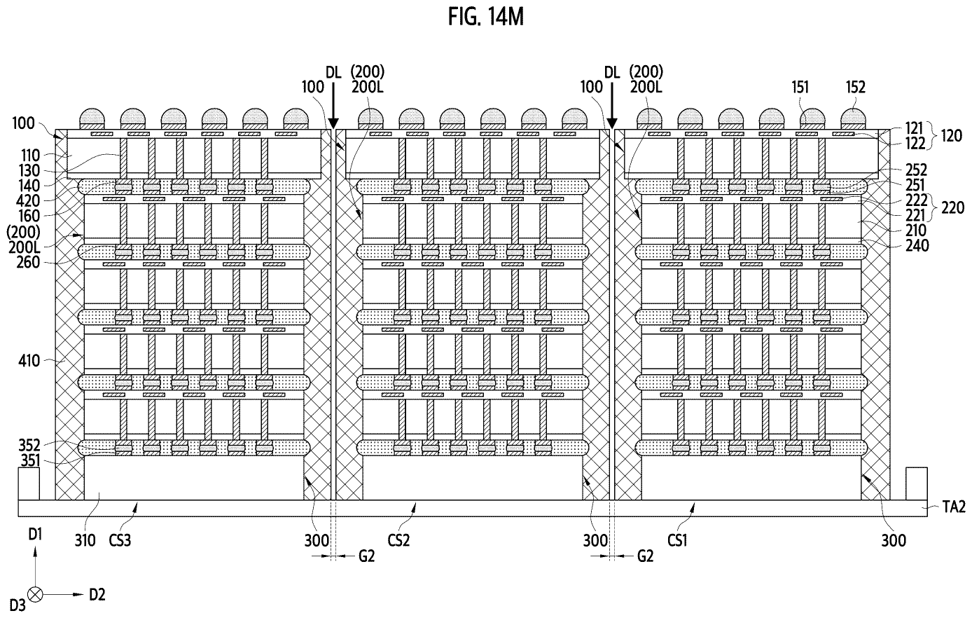

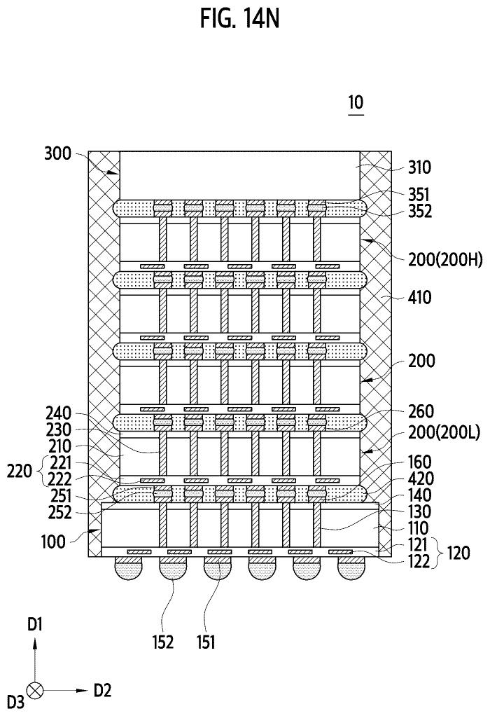

In some implementations, as illustrated in FIG. 3, the thickness T1 of the first part 410_p of the molding layer 410 may be greater than the distance W1 between the side 100s of the first semiconductor chip 100 and the side 200s of the second semiconductor chip 200, which face the same direction and intersect the second direction D2. As will be explained in more detail later with reference to FIG. 14M, in the process of dicing a molding material 411, depending on the size of a second gap G2 of a dicing line DL, the length relationship may vary between the thickness T1 of the first part 410_p of the molding layer 410 and the distance W1 between the side 100s of the first semiconductor chip 100 and the side 200s of the second semiconductor chip 200.

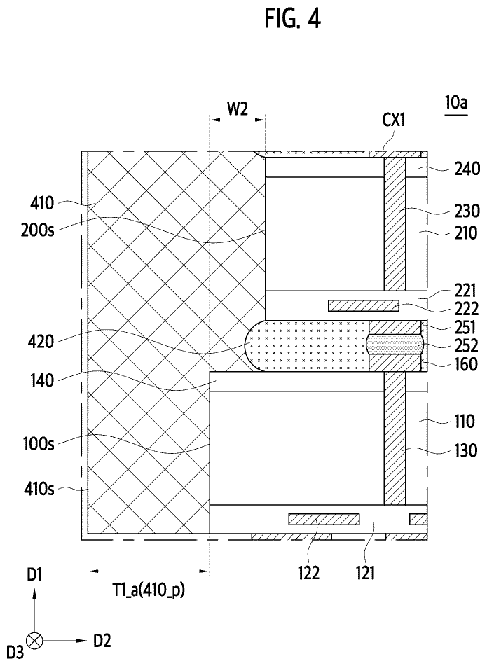

FIG. 4 is an example enlarged view of the portion marked “CX1” in FIG. 2. FIG. 4 illustrates a portion of a semiconductor device.

A semiconductor device 10a illustrated in FIG. 4 is identical or substantially identical or similar to the semiconductor device 10 illustrated in FIG. 1 to FIG. 3, except that smaller than the thickness T1_a of the first part 410_p of the molding layer 410 is the distance W2 between the side 100s of the first semiconductor chip 100 and the side 200s of the second semiconductor chip 200, which face the same direction and intersect the second direction D2. As mentioned with reference to FIG. 3, in the process of dicing the molding material 411 illustrated in FIG. 14M, depending on the size of the second gap G2 of the dicing line DL, the length relationship may vary between the thickness T1_a of the first part 410_p of the molding layer 410 and the distance W2 between the side 100s of the first semiconductor chip 100 and the side 200s of the second semiconductor chip 200.

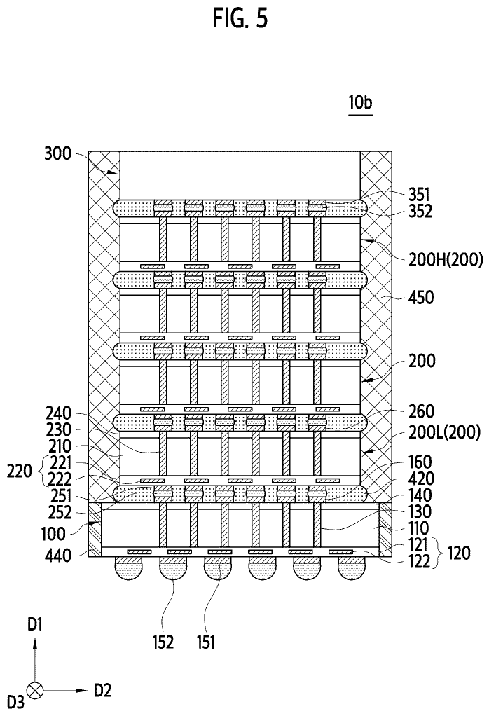

FIG. 5 is a cross-sectional view illustrating an example of a semiconductor device.

A semiconductor device 10b illustrated in FIG. 5 is identical or substantially identical or similar to the semiconductor device 10 illustrated in FIG. 1 to FIG. 3, except that the semiconductor device 10b includes a first molding layer 440 encapsulating the first semiconductor chip 100 and a second molding layer 450 encapsulating the plurality of second semiconductor chips 200. Therefore, descriptions on the elements already mentioned with reference to FIG. 1 to FIG. 3 are omitted, or briefed.

Referring to FIG. 5, the semiconductor device 10b may include the first molding layer 440 surrounding the first semiconductor chip 100, and the second molding layer 450 surrounding the plurality of second semiconductor chips 200 and the dummy chip 300. The second molding layer 450 may be placed on the first molding layer 440. Even though FIG. 5 illustrates that the upper surface of the first molding layer 440 is located on the same plane as the upper surface of the first semiconductor chip 100, according to an example implementation, the upper surface of the first molding layer 440 may not be located in the same plane as the upper surface of the first semiconductor chip 100. In some implementations, the upper surface of the first molding layer 440 may be located at a higher level in the first direction D1 than the upper surface of the first semiconductor chip 100. Alternatively, the upper surface of the first molding layer 440 may be located at a lower level in the first direction D1 than the upper surface of the first semiconductor chip 100.

In some implementations, the maximum thickness of the second molding layer 450 may be greater than the maximum thickness of the first molding layer 440. The thickness referred to here means the thickness in the second direction D2 and/or the third direction D3.

In some implementations, since the second molding layer 450 is in contact with the side of the second substrate 210 and the side of the under-filling layer 420, the thickness may not be constant in the first direction D1. The thickness of the second molding layer 450 may vary depending on the profile of the side of the second substrate 210 and the side of the under-filling layer 420. However, the first molding layer 440 may have a constant thickness in the first direction D1.

In some implementations, when the upper surface of the first molding layer 440 has a higher vertical level than the upper surface of the first semiconductor chip 100, the first molding layer 440 may come into contact with the under-filling layer 420 or the side of the second semiconductor chip 200. Thus, the thickness thereof may vary based on the upper surface of the first semiconductor chip 100.

In some implementations, the thermal expansion coefficient of the first molding layer 440 may be different from the thermal expansion coefficient of the second molding layer 450. Since the thermal expansion coefficient of the first molding layer 440 and the thermal expansion coefficient of the second molding layer 450 are different, the warpage of the semiconductor device 10b may be improved. The semiconductor device 10b has a structure in which a plurality of chips are stacked in the first direction D1, and depending on the vertical level difference, the stress applied to the second molding layer 450 and the stress applied to the first molding layer 440 may be different. The stress referred to here may be stress due to thermal expansion. For example, the thermal expansion coefficient of the first molding layer 440 may be greater than the thermal expansion coefficient of the second molding layer 450. Alternatively, the thermal expansion coefficient of the first molding layer 440 may be smaller than the thermal expansion coefficient of the second molding layer 450. Depending on the difference in thermal expansion coefficient, the stress due to thermal expansion applied to the first molding layer 440 and the second molding layer 450 may differ. Therefore, the difference in stress due to the difference in vertical level may be compensated.

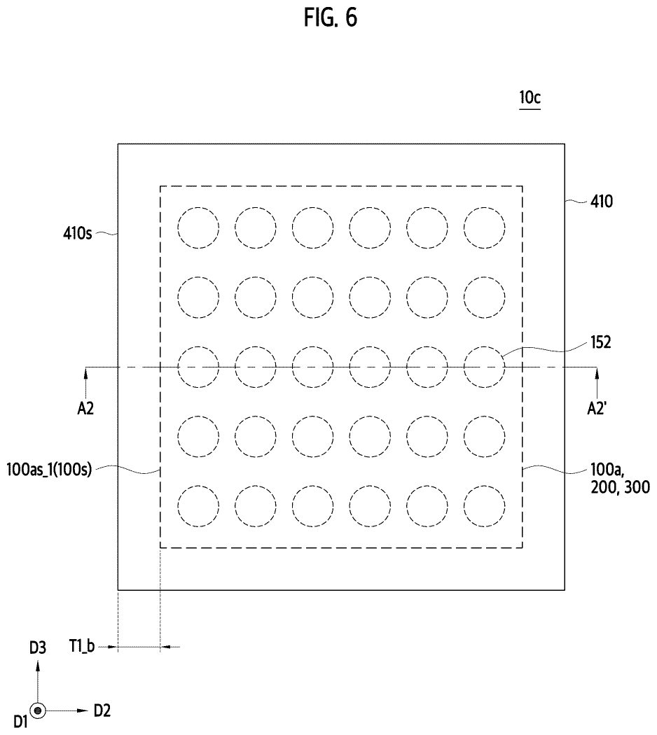

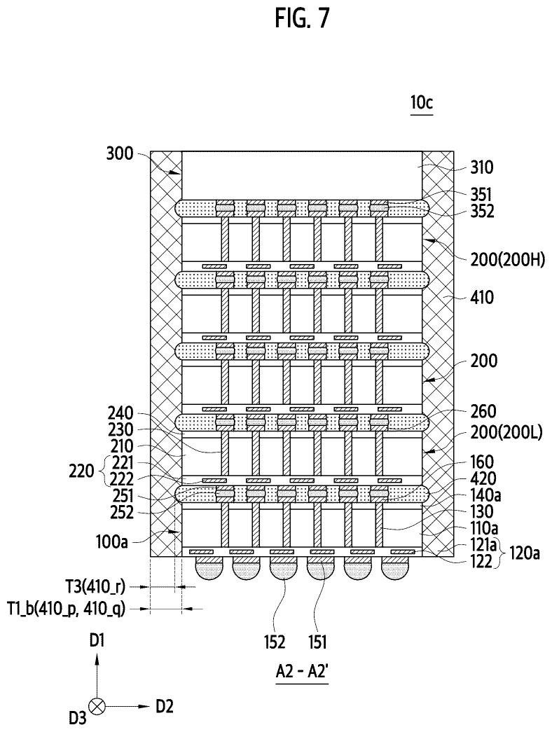

FIG. 6 is a schematic plan view illustrating an example of a semiconductor device, and FIG. 7 is a drawing illustrating an example of a cross-section taken along line A2-A2′ of FIG. 6.

A semiconductor device 10c illustrated in FIG. 6 and FIG. 7 is identical or substantially identical or similar to the semiconductor device 10 illustrated in FIG. 1 to FIG. 3, except that the width of a first semiconductor chip 100a and the width of the second semiconductor chip 200 are the same. Therefore, descriptions on the elements already mentioned with reference to FIG. 1 to FIG. 3 are omitted, or briefed.

In some implementations, the semiconductor device 10c may include the first semiconductor chip 100a, and the plurality of second semiconductor chips 200 stacked along the first direction D1 on the first semiconductor chip 100a. Here, the side of the first semiconductor chip 100a and the side of the second semiconductor chip 200 may be aligned. Equal may be the width in the lateral direction (the second direction D2 and/or the third direction D3) of the first semiconductor chip 100a and the width in the lateral direction (the second direction D2 and/or the third direction D3) of the second semiconductor chip 200.

In some implementations, an area in contact with the side of the first semiconductor chip 100a of the molding layer 410 may be defined as the first part 410_p, and an area in contact with the side of the second semiconductor chip 200 of the molding layer 410 may be defined as the second part 410_q. Further, an area in contact with the side of the under-filling layer 420 of the molding layer 410 may be defined as a third part 410_r.

In some implementations, the thickness T1_b of the first part 410_p and the thickness T1_b of the second part 410_q may be the same. In some implementations, the thickness T1_b of the first part 410_p and the thickness T1_b of the second part 410_q may be the same since the width of the first semiconductor chip 100a in the lateral direction (the second direction D2 and/or the third direction D3) is equal to the width of the second semiconductor chip 200 in the lateral direction (the second direction D2 and/or the third direction D3), and the side of the first semiconductor chip 100a and the side of the second semiconductor chip 200 are aligned. For example, the thickness T1_b of the first part 410_p and the second part 410_q may be in the range of 30 μm to 300 μm.

In some implementations, the thickness T3 of the third part 410_r may be smaller than the thickness T1_b of the first part 410_p and the second part 410_q since the under-filling layer 420 protrudes laterally (the second direction D2 and/or the third direction D3) from the side of the first semiconductor chip 100a and the side of the second semiconductor chip 200. Here, the thickness T3 of the third part 410_r may be smaller than the thickness T1_b of the first part 410_p and the second part 410_q in the range of over 30 μm to 300 μm.

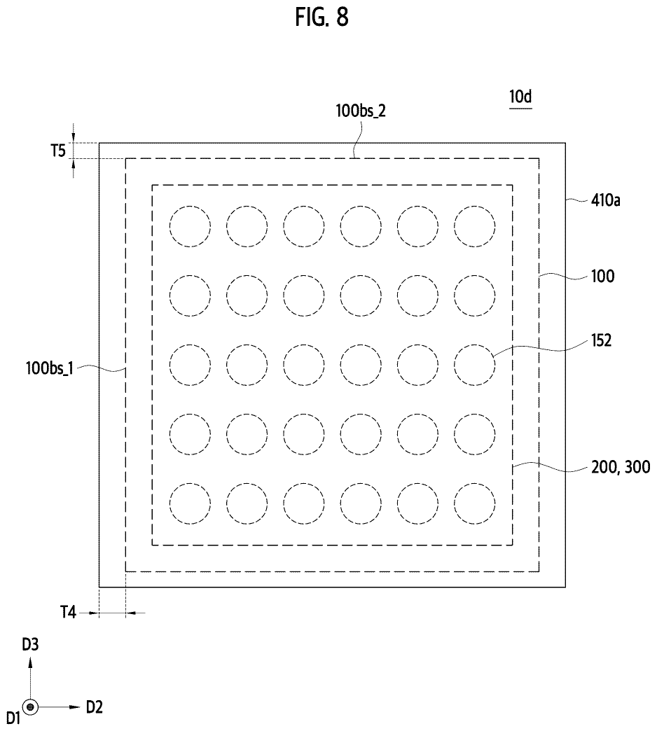

FIG. 8 is a schematic plan view illustrating an example of a semiconductor device 10d. Below, differences from the semiconductor device 10 illustrated in FIG. 1 to FIG. 3 are mainly explained.

Referring to FIG. 8, the thickness T4 of a molding layer 410a covering a first side 100bs_1 intersecting with second direction D2 of the first semiconductor chip 100 may be different from the thickness T5 of the molding layer 410a covering a second side 100bs_2 intersecting with the first side 100bs_1 of the first semiconductor chip 100. For example, the thickness T4 of the molding layer 410a covering the first side 100bs_1 may be greater than the thickness T5 of the molding layer 410a covering the second side 100bs_2.

As will be explained in more detail later with reference to FIG. 14M, in the process of dicing the molding material 411, depending on the size or location of the second gap G2 of the dicing line DL, the thickness T4 of the molding layer 410a covering the first side 100bs_1 of the first semiconductor chip 100 and the thickness T5 of the molding layer 410a covering the second side 100bs_2 of the first semiconductor chip 100 may be different from each other. For example, when the gap of the dicing line extending along the second direction D2 among the dicing lines shown in FIG. 14M is smaller than the gap of the dicing line extending along the third direction D3, as in the example implementation of FIG. 8, the thickness T4 of the molding layer 410a covering the first side 100bs_1 may be greater than the thickness T5 of the molding layer 410a covering the second side 100bs_2.

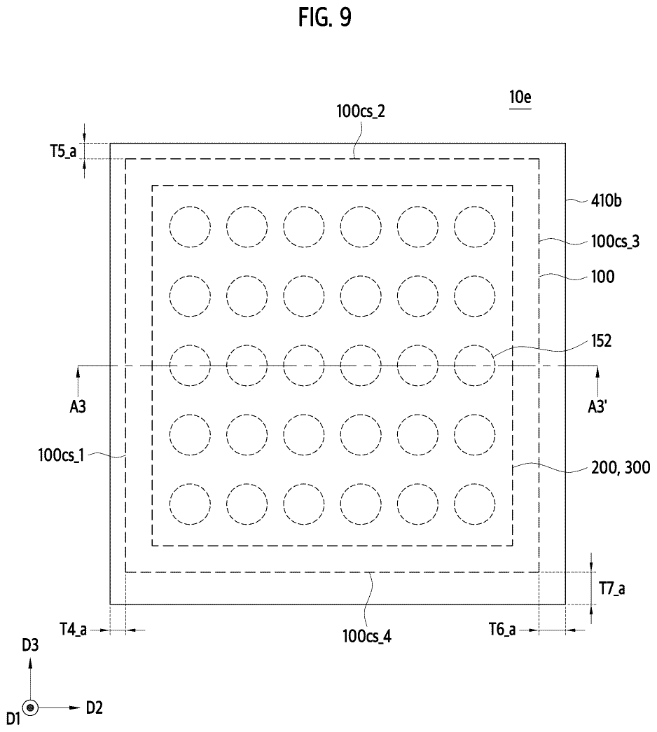

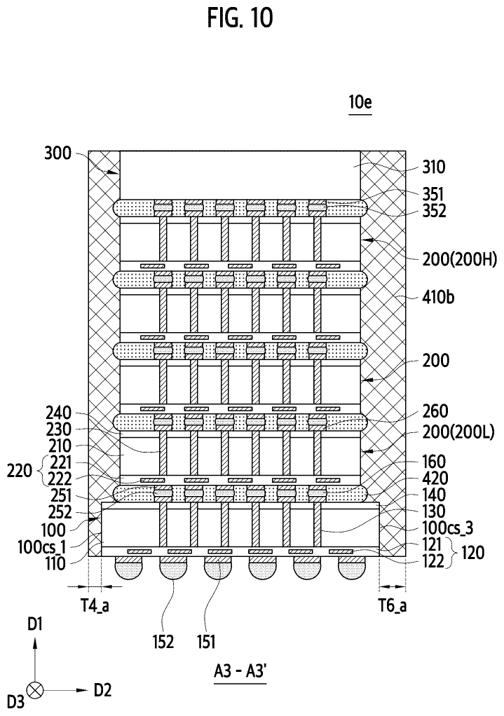

FIG. 9 is a schematic plan view illustrating an example of a semiconductor device, and FIG. 10 is a drawing illustrating an example of a cross-section taken along line A3-A3′ of FIG. 9. Below, differences from the semiconductor devices illustrated in FIG. 1 to FIG. 3 are specifically explained.

Referring to FIG. 9, the first semiconductor chip 100 may have a first side 100cs_1 and a third side 100cs_3 that intersect with the second direction D2 and are opposite to each other. In addition, the first semiconductor chip 100 may have a second side 100cs_2 and a fourth side 100cs_4 that intersect with the third direction D3 and are opposite to each other.

In some implementations, parts of a molding layer 410b that contact the four sides (the first side 100cs_1, the second side 100cs_2, the third side 100cs_3 and the fourth side 100cs_4) of the first semiconductor chip 100 may have different thicknesses from each other. For example, the thickness T5_a of a part of the molding layer 410b that is in contact with the second side 100cs_2 of the second semiconductor chip 200 may be greater than the thickness T4_a of a part of the molding layer 410b that is in contact with the first side 100cs_1 of the first semiconductor chip 100. For example, the thickness T6_a of a part of the molding layer 410b that is in contact with the third side 100cs_3 of the second semiconductor chip 200 may be greater than the thickness T5_a of a part of the molding layer 410b that is in contact with the second side 100cs_2 of the first semiconductor chip 100. For example, the thickness T7_a of a part of the molding layer 410b that is in contact with the fourth side 100cs_4 of the second semiconductor chip 200 may be greater than the thickness T6_a of a part of the molding layer 410b that is in contact with the third side 100cs_3 of the first semiconductor chip 100. However, it is only pertains to an example implementation, and the thickness of the molding layer 410b does not necessarily have to increase clockwise in a horizontal view as illustrated in FIG. 9 according to the example implementation. The example implementations illustrated in FIG. 9 and FIG. 10 only pertain to example implementations indicating the difference between the thicknesses of the parts of the molding layer 410b that contact the four sides (the first side 100cs_1, the second side 100cs_2, the third side 100cs_3, and the fourth side 100cs_4) of the first semiconductor chip 100.

As will be explained in more detail later with reference to FIG. 14M, in the process of dicing the molding material 411, depending on the size or location of the second gap G2 of the dicing line DL, parts of the molding layer 410b that contact the four sides (the first side 100cs_1, the second side 100cs_2, the third side 100cs_3, and the fourth side 100cs_4) of the first semiconductor chip 100 may have different thicknesses from each other. For example, according to the second gap G2 or position of the dicing line DL corresponding to each of the four sides of the molding layer 410b shown in FIG. 9 among the dicing line DL shown in FIG. 14M, parts of the molding layer 410b that contact the four sides (the first side 100cs_1, the second side 100cs_2, the third side 100cs_3 and the fourth side 100cs_4) of the first semiconductor chip 100 may have different thicknesses from each other.

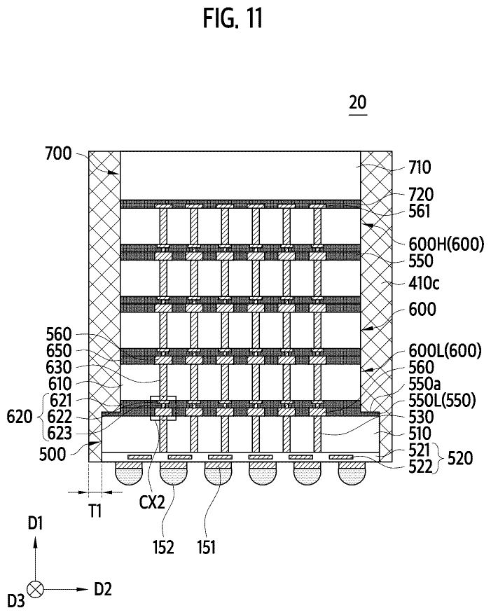

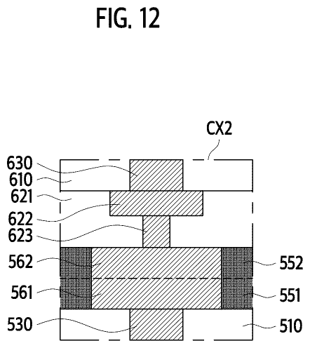

FIG. 11 is a cross-sectional view illustrating an example of a semiconductor device, and FIG. 12 is an example enlarged view of the portion marked “CX2” in FIG. 11.

Unlike the semiconductor device 10 illustrated in FIG. 1 to FIG. 3, a semiconductor device 20 illustrated in FIG. 11 and FIG. 12 may have a first semiconductor chip 500 and a plurality of second semiconductor chips 600 attached to each other in a hybrid bonding manner. Hereinafter, differences from the semiconductor device 10 illustrated in FIG. 1 to FIG. 3 are specifically described.

In some implementations, the first semiconductor chip 500 may include a first substrate 510, a first interconnection structure 520, a first through electrode 530, a chip connecting insulation layer 550 and a chip connecting pad 560. The first interconnection structure 520 may include a first insulation layer 521 and a first interconnection 522. The first substrate 510, the first interconnection structure 520 and the first through electrode 530 are identical or substantially identical to the first substrate 110, the first interconnection structure 120 and the first through electrode 130 illustrated in FIG. 1 to FIG. 3. Thus, specific descriptions are omitted.

In some implementations, among the plurality of second semiconductor chips 600, a second interconnection pattern 622 and/or a second interconnection via 623 of a second interconnection structure 620 of a bottom second semiconductor chip 600L may be electrically connected to a plurality of first through electrodes 530 included in the first semiconductor chip 500 located at the lower side through a plurality of chip connecting pads 560.

In some implementations, between the first semiconductor chip 500 and the bottom second semiconductor chip 600L, the plurality of chip connecting pads 560 may be surrounded by the chip connecting insulation layer 550. The plurality of chip connecting pads 560 may penetrate (e.g., extend into) the chip connecting insulation layer 550. Among the plurality of chip connecting insulation layers 550, a bottom chip connecting insulation layer 550L may be interposed between the first semiconductor chip 500 and the bottom second semiconductor chip 600L.

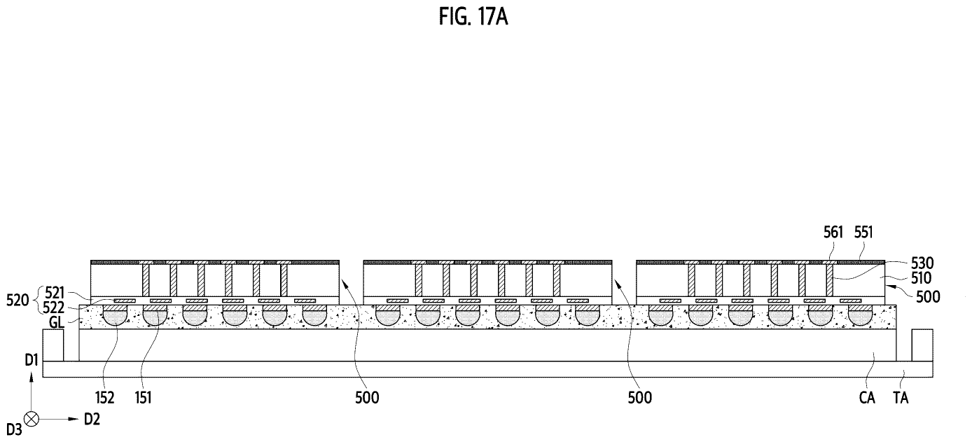

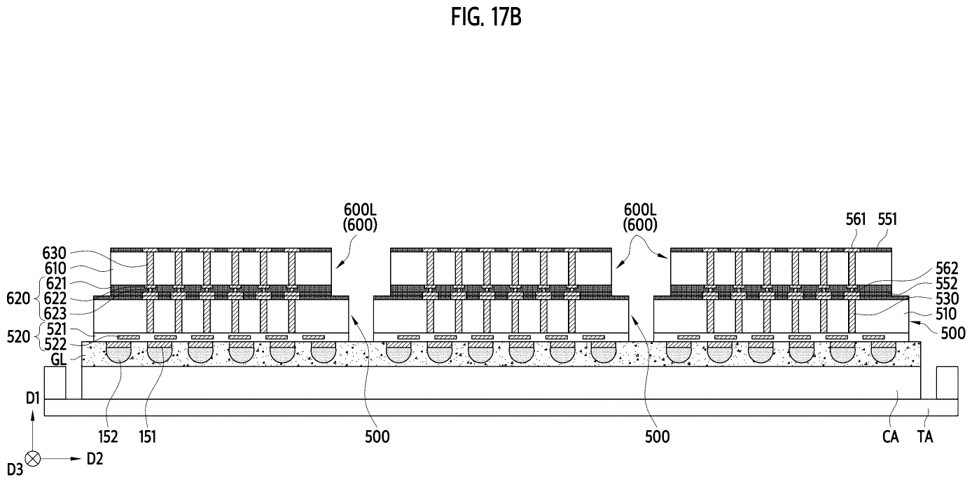

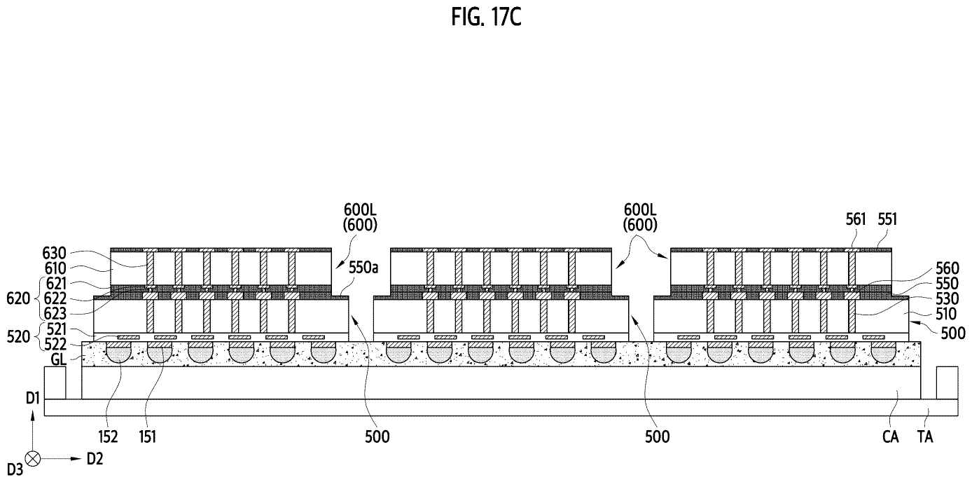

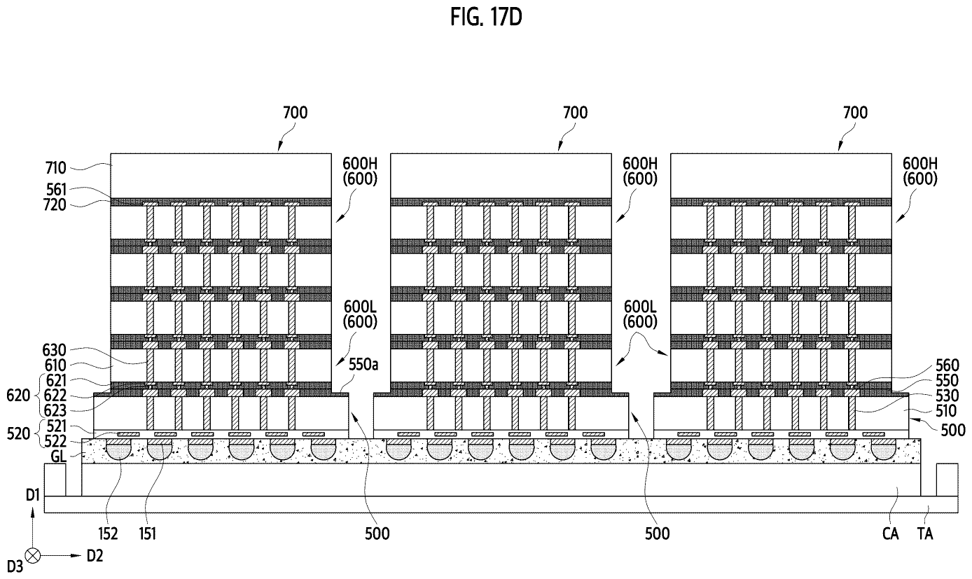

In some implementations, each of the plurality of chip connecting pads 560 may include a conductive material layer formed on respective facing surfaces of two adjacent chip among the first semiconductor chip 500 and the plurality of second semiconductor chips 600. The conductive material layer may include, for example, a plurality of upper chip connecting pads 561 and a plurality of lower chip connecting pads 562, as illustrated in FIG. 17B. Subsequently, the conductive material layers facing each other may come into contact with each other by thermal expansion and may be diffusion-bonded through atomic diffusion of constituent metal atoms to form an integral structure. As illustrated in FIG. 12, the plurality of chip connecting pads 560 may be formed by directly bonding the lower chip connecting pad 562 and the upper chip connecting pad 561. The lower chip connecting pad 562 may be connected to the first through electrode 530, and the upper chip connecting pad 561 may be connected to the second interconnection via 623.

In some implementations, the chip connecting insulating layer 550 may be formed by insulating material layer at each of surface facing each other of two chips neighboring among the first semiconductor chip 500 and the plurality of second semiconductor chips 600, for example, insulating material layers facing each other in the process of forming the chip connecting insulation layer 550 after an upper chip connecting insulation layer 551 and a lower chip connecting insulation layer 552 illustrated in FIG. 17B are formed contacting each other by expansion by the heat, and by diffusion bonding to form a whole through the diffusion of the constituent metal atoms. As illustrated in FIG. 12, the chip connecting insulation layer 550 may be formed by directly bonding the upper chip connecting insulation layer 551 and the lower chip connecting insulation layer 552.

In some implementations, in order for the thickness of the part overlapping the bottom second semiconductor chip 200L in the first direction D1 to have a value greater than the part that does not overlap with the bottom second semiconductor chip 200L in the first direction D1, the bottom chip connecting insulation layer 550L may have a recess 550a on its upper part. The recess 550a may be located in a part of the bottom chip connecting insulation layer 550L that does not overlap with the bottom second semiconductor chip 200L in the first direction D1. The bottom chip connecting insulation layer 550L may have a shape in which the middle part, which is the part that overlaps the bottom second semiconductor chip 200L in the first direction D1, protrudes upwards more than the edge parts, which do not overlap with the bottom second semiconductor chip 200L in the first direction D1. The bottom chip connecting insulation layer 550L may have a flat lower surface.

In some implementations, the bottom chip connecting insulation layer 550L may cover the entire upper surface of the first semiconductor chip 500 that does not overlap with the bottom second semiconductor chip 200L in the first direction D1. The plurality of chip connecting pads 560 may cover a portion of the upper surface of the first semiconductor chip 500 overlapping the bottom second semiconductor chip 200L in the first direction D1 and a portion of the lower surface of the bottom second semiconductor chip 200L, and the bottom chip connecting insulation layer 550L may cover the other portions.

In some implementations, the remaining chip connecting insulation layer 550 except for the bottom chip connecting insulation layer 550L may cover both the upper surface and the lower surface of the second semiconductor chip 600, which face each other, together with the plurality of chip connecting pads 560. The remaining chip connecting insulation layer 550 except for the bottom chip connecting insulation layer 550L may have flat upper and lower surfaces with generally the same thickness.

In some implementations, a dummy chip 700 may include a supportive dummy substrate 710 and a supportive connection insulation layer 720. The supportive connection insulation layer 720 may be interposed between a top second semiconductor chip 600H and the supportive dummy substrate 710. The supportive connection insulation layer 720 may be formed by forming the insulating material layer on each of the upper surface of the top second semiconductor chip 600H and the lower surface of the supportive dummy substrate 710 facing each other, the insulating material layers facing each other expanding due to heat and coming into contact with each other, and by constituting elements being diffusion bonded to form a whole.

In some implementations, only semiconductor material may be exposed on the lower surface of the supportive dummy substrate 710. Therefore, the upper surface of the supportive connection insulation layer 720 may only come into contact with the semiconductor material. The supportive connection insulation layer 720 may cover the entire lower surface of the supportive dummy substrate 710. In some implementations, when the plurality of upper chip connecting pads 561 are placed on the upper surface of the top second semiconductor chip 600H, the supportive connection insulation layer 720 may surround the plurality of upper chip connecting pads 561. For example, the supportive connection insulation layer 720 may cover the upper surface, or, the inactive surface, of a second substrate 610 of the top second semiconductor chip 600, and cover the sides and upper surfaces of the plurality of upper chip connecting pads 561. The plurality of upper chip connecting pads 561 may be spaced from the supportive dummy substrate 710 with the supportive connection insulation layer 720 therebetween. In some implementations, when the plurality of upper chip connecting pads 561 are not placed on the upper surface of the top second semiconductor chip 600H, the supportive connection insulation layer 720 may cover the upper surface of the second substrate 610 of the top second semiconductor chip 600H, and cover a plurality of second through electrodes 630 exposed on the upper surface of the second substrate 610 of the top second semiconductor chip 600H.

In some implementations, the chip connecting insulation layer 550 and the supportive connection insulation layer 720 may be made of any one of SiO, SiN, SiCN, SiCO, and a high molecular substance. The high molecular substance may be Benzocyclobutene (BCB), Polyimide (PI), Polybenzoxazole (PBO), silicone, acrylate or epoxy. For example, the chip connecting insulation layer 550 and the supportive connection insulation layer 720 may be made of silicon oxide. In some implementations, the chip connecting insulation layer 550 and the supportive connection insulation layer 720 may be made of the same material. The chip connecting insulation layer 550 and the supportive connection insulation layer 720 may have a thickness of, for example, about 100 nm to about 1 μm. The plurality of chip connecting pads 560 may be formed of a material including copper (Cu).

In some implementations, a molding layer 410c may seal the first semiconductor chip 500, the plurality of second semiconductor chips 600 and the dummy chip 700. The molding layer 410c may surround the first semiconductor chip 500, the plurality of second semiconductor chips 600 and the dummy chip 700. As illustrated in FIG. 1 to FIG. 3, the thickness of a portion of the molding layer 410c that contacts the first semiconductor chip 500 may be smaller than the thickness of a portion of the molding layer 410c that contacts the second semiconductor chip 600. A specific description of this is similar to what is described with reference to FIG. 1 to FIG. 3, and thus the specific description is omitted.

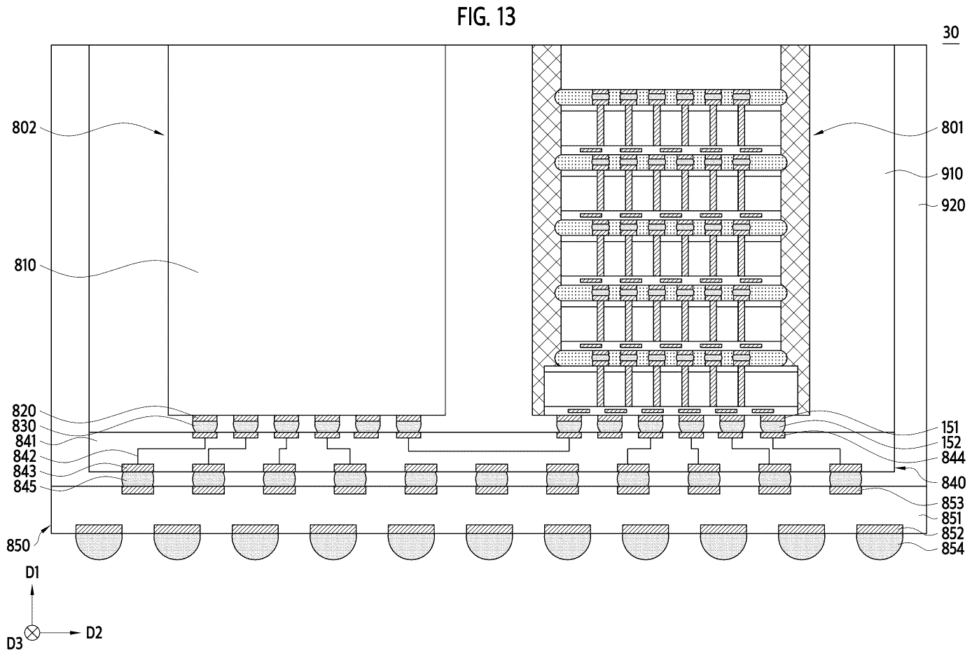

FIG. 13 is a cross-sectional view illustrating an example of a semiconductor package 30.

The semiconductor package 30 illustrated in FIG. 13 is a semiconductor package in which a first semiconductor device 801 is mounted. The semiconductor package 30 illustrated in FIG. 13 may include the first semiconductor device 801, a second semiconductor device 802, an interposer 840, a package substrate 850, a first package sealing layer 910 and a second package sealing layer 920.

In some implementations, the first semiconductor device 801 and the second semiconductor device 802 may be mounted on the interposer 840. The first semiconductor device 801 may be a semiconductor device (semiconductor devices 10, 10a, 10b, 10c, 10d, 10e, 20 and 30 described with reference to FIG. 2, FIG. 4, FIG. 5, FIG. 7, FIG. 8, FIG. 9, FIG. 10, FIG. 11, and FIG. 13). Description on the first semiconductor device 801 overlaps with the description made with reference to the previous drawings, and thus the description on the first semiconductor device 801 is omitted.

In some implementations, the interposer 840 may include an interposer substrate 841, an interposer interconnection 842, an interposer lower pad 843, an interposer upper pad 844 and an interposer connecting terminal 845.

In some implementations, the interposer substrate 841 may include an upper surface on which the first semiconductor device 801 and the second semiconductor device 802 may be mounted and a lower surface opposite thereto. The first semiconductor device 801 and the second semiconductor device 802 may be mounted on the upper surface of the interposer substrate 841. The interposer substrate 841 may be, for example, a silicon interposer. Alternatively, the interposer substrate 841 may include, for example, at least one of glass, ceramic and plastic.

In some implementations, the interposer upper pad 844 may be positioned on the upper surface of the interposer substrate 841. The interposer upper pad 844 may provide a terminal for electrically connecting the first semiconductor device 801 and the second semiconductor device 802 mounted on the interposer substrate 841. Specifically, the first connecting bump 152 of the first semiconductor device 801 and a fourth connecting bump 830 of the second semiconductor device 802 may be attached to the interposer upper pad 844. The interposer lower pad 843 may be placed on the lower surface of the interposer substrate 841. The interposer connecting terminals 845 may be attached to the interposer lower pad 843. The interposer connecting terminal 845 may be a terminal for connecting the interposer 840 to the package substrate 850. For example, the material included in the interposer upper pad 844 and the interposer lower pad 843 may be identical or substantially identical to the material included in the first connecting pad 151 illustrated in FIG. 2. Further, the material included in the interposer connecting terminal 845 may be identical or substantially identical to the material included in the first connecting bump 152 illustrated in FIG. 2. In some implementations, the first semiconductor device 801 and the second semiconductor device 802 may be mounted on the interposer 840 in a flip chip manner.

In some implementations, the interposer interconnection 842 may be positioned within the interposer substrate 841. The interposer interconnection 842 may include a plurality of vias extending in a direction (for example, the first direction D1) from the upper surface of the interposer substrate 841 toward the lower surface. Alternatively, the interposer interconnection 842 may include a plurality of interconnections extending in a direction parallel to the upper surface of the interposer substrate 841 (for example, the second direction D2 and/or the third direction D3). The interposer interconnection 842 may include a metal material such as copper (Cu) or aluminum (Al), but is not limited thereto. The number, spacing and arrangement of the interposer interconnections 842 are exemplary, and thus the number, spacing and arrangement of the interposer interconnections 842 are not limited thereto.

In some implementations, the interposer interconnection 842 may be electrically connected to the package substrate 850. The interposer interconnection 842 may include a ground pattern, a power pattern, or a signal pattern.

In some implementations, the second semiconductor device 802 may include a semiconductor substrate 810, a fourth connecting pad 820, and the fourth connecting bump 830. The lower surface of the semiconductor substrate 810 may be the active surface, and the upper surface of the semiconductor substrate 810 may be an inactive surface. The semiconductor substrate 810 may include, for example, silicon. Alternatively, the semiconductor substrate 810 may include a semiconductor material such as germanium, or a compound semiconductor such as SiC, GaAs, InAs and InP. The semiconductor substrate 810 may include a conductive area, for example, a doped well, or a doped structure. The semiconductor device layer including individual devices may be provided on the active surface of the semiconductor substrate 810. For example, the individual devices may include transistors. The individual devices include microelectronic devices. For example, included may be metal-oxide-semiconductor field effect transistors (MOSFET), such as complementary metal-insulator-semiconductor (CMOS) transistors, system large scale integration (LSI) circuits, image sensors such as CMOS imaging sensors (CIS), micro-electro-mechanical systems (MEMS), active devices, and/or passive devices.

In some implementations, the first semiconductor device 801 is a semiconductor device consisting of memory chips, and the second semiconductor device 802 may be a semiconductor device consisting of a logic chip.

In some implementations, the fourth connecting pad 820 is arranged on the lower surface of the semiconductor substrate 810 and may be electrically connected to individual devices of the semiconductor device layer. The fourth connecting bumps 830 may be attached to the fourth connecting pad 820. The fourth connecting bump 830 may be a terminal for connecting the second semiconductor device 802 to the interposer 840. For example, the material included in the fourth connecting pad 820 may be identical or substantially identical to the material included in the first connecting pad 151 illustrated in FIG. 2. Further, the material included in the fourth connecting bump 830 may be identical or substantially identical to the material included in the first connecting bump 152 illustrated in FIG. 2.

In some implementations, the package substrate 850 may include a base substrate 851, a package lower pad 852, a package upper pad 853 and a package connecting terminal 854.

In some implementations, the base substrate 851 may include an upper and a lower surface opposite to each other. For example, the base substrate 851 may be a printed circuit board (PCB). When the base substrate 851 is a PCB, the base substrate 851 may be composed of at least one material selected from phenol resin, epoxy resin and polyimide. For example, the base substrate 851 may include at least one material selected from FR4, tetrafunctional epoxy, polyphenylene ether, epoxy/polyphenylene oxide, bismaleimide triazine (BT), thermount, cyanate ester, polyimide, and liquid crystal polymer.

In some implementations, the package lower pad 852 may be placed on the lower surface of the base substrate 851. The package upper pad 853 may be placed on the upper surface of the base substrate 851. The package upper pad 853 may provide a terminal for electrical connection of the interposer 840 mounted on the base substrate 851. Specifically, the interposer connecting terminal 845 of the interposer 840 may be attached to the package upper pad 853. The package lower pad 852 may be placed on the lower surface of the base substrate 851. The package connecting terminals 854 may be attached to the package lower pad 852. The package connecting terminal 854 may be a terminal for connecting the semiconductor package 30 to another device. For example, the material included in the package upper pad 853 and the package lower pad 852 may be identical or substantially identical to the material included in the first connecting pad 151 illustrated in FIG. 2. Further, the material included in the package connecting terminal 854 may be identical or substantially identical to the material included in the first connecting bump 152 illustrated in FIG. 2.

In some implementations, the first package sealing layer 910 may seal the first semiconductor device 801 and the second semiconductor device 802 on the interposer substrate 841. The first package sealing layer 910 may enclose the first semiconductor device 801 and the second semiconductor device 802. The top surface of the first package sealing layer 910 may be positioned on the same plane as the top surface of the first semiconductor device 801 and the top surface of the second semiconductor device 802. The side of the first package sealing layer 910 may be aligned with the side of the interposer substrate 841.

In some implementations, the second package sealing layer 920 may seal the interposer 840 and the first package sealing layer 910 on the package substrate 850. The second package sealing layer 920 may wrap the interposer 840 and the first package sealing layer 910. The top surface of the second package sealing layer 920 may be positioned on the same plane as the top surface of the first semiconductor device 801, the top surface of the second semiconductor device 802, and the top surface of the first package sealing layer 910.

For example, the first package sealing layer 910 and the second package sealing layer 920 may be made of the EMC. The first package sealing layer 910 and the second package sealing layer 920 may include pillars. For example, the pillar may be made of silica. The pillar may have a size of, for example, one-digit number um to two-digit number um, and may have an average size of about 2 to 10 μm.

FIGS. 14A, 14B, 14C, 14D, 14E, 14F, 14G, 14H, 14I, 14J, 14K, 14L, 14M, and 14N are cross-sectional views illustrating a process sequence for explaining an example of a method of manufacturing a semiconductor device.

FIG. 14A is a cross-sectional view illustrating an operation of preparing the first substrate 110.

Referring to FIG. 14A, a semiconductor wafer W is prepared. The semiconductor wafer W may be composed of a plurality of semiconductor chips C separated by scribe lanes SL. Each of the plurality of semiconductor chips C may include the first substrate 110, the first through electrode 130, the first insulation layer 121 and the first interconnection 122. Here, the first substrate 110 and the first insulation layer 121 included in the plurality of semiconductor chips C are one substrate and one insulation layer forming an integral whole.

In some implementations, the first substrate 110 may include an active surface and an inactive surface opposite to each other. A first surface 111a of the first substrate 110 illustrated in FIG. 14A may be an inactive surface. The first through electrode 130 may extend from the active surface of the first substrate 110 into the interior of the wafer W. At least a portion of the first through electrode 130 may be columnar in shape.

In some implementations, the first insulation layer 121 may be formed on the active surface of the semiconductor wafer W. The first insulation layer 121 may extend along the active surface of the semiconductor wafer W. The side of the first insulation layer 121 may be aligned with the side of the semiconductor wafer W. The plurality of first interconnections 122 may be arranged within the first insulation layer 121.

Referring to FIG. 14B, the first connecting bump 152 may be formed on the first substrate 110 and electrically connected to the first through electrode 130. Before the first connecting bump 152 is formed, the first connecting pad 151 may be further formed to be positioned between the first connecting bump 152 and the first insulation layer 121. In some implementations, the first connecting pad 151 may be electrically connected to a portion of the first interconnection 122 exposed on the upper surface of the first insulation layer 121.

FIG. 14C is a cross-sectional view illustrating an operation of attaching the semiconductor wafer W to a carrier substrate CA according to an example implementation.

Referring to FIG. 14C, the semiconductor wafer W on which the first connecting bump 152 is formed may be attached to the carrier substrate CA. Here, an adhesive material layer GL may be formed on the carrier substrate CA. The semiconductor wafer W may be attached to the carrier substrate CA in order for the first connecting bump 152 to face the carrier substrate CA. The first connecting bump 152 may be wrapped by the adhesive material layer GL. A portion of the lower surface of the first insulation layer 121 that is not covered by the first connecting bump 152 and is exposed may come into contact with the adhesive material layer GL.

FIG. 14D is a cross-sectional view illustrating the operation of exposing the first through electrode 130 according to an example implementation.

Referring to FIG. 14D, the upper portion of the first substrate 110 is removed to expose the first through electrode 130. Before the upper portion of the first substrate 110 is removed, the vertical level along the first direction D1 of the first surface 111a (see FIG. 14C) of the first substrate 110 is positioned higher than the vertical level of the first through electrode 130. As the upper portion of the first substrate 110 is removed, the first through electrode 130 may be exposed on an upper surface 111 of the first substrate 110. Since the first through electrode 130 is exposed to the upper surface 111 of the first substrate 110, the first through electrode 130 may have a shape that penetrates (e.g., extends into) the first substrate 110. In order for the first through electrode 130 to protrude beyond the upper surface 111, a portion of the first substrate 110 may be optionally removed. A portion of the first substrate 110 may be removed using a chemical mechanical polishing (CMP) process, an etch-back process, or a combination thereof to expose the first through electrode 130.

FIG. 14E is a cross-sectional view illustrating an operation of forming the first back side protection layer 140 and the first back side pad 160 according to an example implementation.

Referring to FIG. 14E, the first back side protection layer 140 is formed covering the exposed surface of the semiconductor wafer W, or, the upper surface of the first substrate 110. For example, the first back side protection layer 140 may be formed by a spin coating process or a spraying process. The first back side protection layer 140 may be made of, for example, an insulating polymer. In order to form the first back side protection layer 140, an insulating polymer film may be formed covering the upper surface of the first substrate 110 and the exposed first through electrode 130, and the insulating polymer film may be partially removed through an etch-back process to expose the first through electrode 130.

After then, the first back side pad 160 is formed that is electrically connected to the first through electrode 130 portion exposed by the first back side protection layer 140.

FIG. 14F is a cross-sectional view illustrating the dicing the semiconductor wafer W illustrated in FIG. 14E along the scribe lane SL.

Referring to FIG. 14F, first, the carrier substrate CA on which the semiconductor wafer W illustrated in FIG. 14E is mounted may be attached to a first tape TA1. After then, the semiconductor wafer W illustrated in FIG. 14E may be diced along the scribe lane SL. Each of the semiconductor chips C may be separated from the first semiconductor chip 100 by physical separation.

In some implementations, the first semiconductor chips 100 may be spaced apart by a first gap G1. Here, the first gap G1 by which the first semiconductor chips 100 are spaced apart may be equal to the width of the scribe lane SL. As the first semiconductor chips 100 are spaced apart from each other by the first gap G1, a plurality of first substrates 110 may also be spaced apart from each other. In the dicing process, the adhesive material layer GL may not be damaged. However, according to an example implementation, a portion of the adhesive material layer GL may as be damaged in the dicing process. In the dicing process, the first substrate 110, the first interconnection structure 120 and the first back side protection layer 140 located in the area corresponding to the scribe lane SL may all be removed.

FIG. 14G is a cross-sectional view illustrating an operation of stacking the second semiconductor chips 200 on the first semiconductor chip 100 according to an example implementation.

Referring to FIG. 14G, the plurality of second semiconductor chips 200 may be stacked on the first semiconductor chip 100 diced in the operation of FIG. 14F. The elements included in the second semiconductor chip 200 are identical to the elements described with reference to FIG. 1 to FIG. 3 and thus detailed description thereon will be omitted.

In some implementations, the plurality of second semiconductor chips 200 may be stacked on the carrier substrate CA to correspond to each of the first semiconductor chips 100. The bottom second semiconductor chip 200L located at the bottom among the plurality of second semiconductor chips 200 may be attached to the first semiconductor chip 100. Among the plurality of second semiconductor chips 200, the second semiconductor chip 200 except the bottom second semiconductor chip 200L may be attached to another second semiconductor chip 200. Among the plurality of second semiconductor chips 200, the dummy chip 300 may be attached to the top second semiconductor chip 200H.

In some implementations, the second semiconductor chips 200 may be stacked on the first semiconductor chip 100 in order for the first through electrode 130 and the second through electrode 230 to be electrically connected. In order for the first through electrode 130 and the second through electrode 230 to be electrically connected, the second connecting bump 252 of the second semiconductor chip 200 may be attached to the first back side pad 160. The second connecting bump 252 of the second semiconductor chip 200 may be electrically connected to the second through electrode 230 via the second interconnection structure 220, and the first back side pad 160 of the first semiconductor chip 100 may be electrically connected to the first through electrode 130. When the first back side pad 160 is not formed, the second connecting bump 252 may contact the first through electrode 130.

In some implementations, among the second semiconductor chips 200 stacked on each other, the second through electrode 230 of the second semiconductor chip 200 located above and the second through electrode 230 of the second semiconductor chip 200 located below may be electrically connected. Here, in order for the second through electrode 230 located above and the second through electrode 230 located below to be electrically connected, the second connecting bump 252 of the second semiconductor chip 200 located above may be attached to the second back side pad 260 of the second semiconductor chip 200 located below. When the second back side pad 260 is not formed, the second connecting bump 252 of the second semiconductor chip 200 located above may come into contact with the second through electrode 230 of the second semiconductor chip 200 located below.

Referring to FIG. 14H, the third connecting bump 352 of the dummy chip 300 may be attached to the second back side pad 260 of the top second semiconductor chip 200H.

In some implementations, after completion of bonding between the second connecting bump 252 and the first back side pad 160, bonding between the second connecting bump 252 and the second back side pad 260 and bonding between the third connecting bump 352 and the second back side pad 260, the under-filling layer 420 may be formed. The under-filling layer 420 may surround the second connecting bump 252 and the first back side pad 160 between the first semiconductor chip 100 and the second semiconductor chip 200. In some implementations, the under-filling layer 420 may cover the entire lower surface of the second semiconductor chip 200. Between the second semiconductor chips 200 stacked along the first direction D1, the under-filling layer 420 may surround the second connecting bump 252 of the second semiconductor chip 200 located above and the second back side pad 260 of the second semiconductor chip 200 located below. The under-filling layer 420 may surround the third connecting bump 352 and the second back side pad 260 between the second semiconductor chip 200 and the dummy chip 300.

In some implementations, as illustrated in FIG. 14H, when the plurality of second semiconductor chips 200 and the dummy chips 300 are stacked on the first semiconductor chips 100 arranged on the carrier substrate CA, the chip structures (a first chip structure CS1, a second chip structure CS2 and a third chip structure CS3) are completed. For example, FIG. 14H illustrates the first chip structure CS1, the second chip structure CS2 and the third chip structure CS3 that are completed on the carrier substrate CA.

FIG. 14H is a cross-sectional view illustrating an operation of forming a molding material on a carrier substrate according to an example implementation.

Referring to FIG. 14H, the molding material 411 may be formed on the carrier substrate CA to surround the first semiconductor chip 100, the plurality of second semiconductor chips 200, and the dummy chip 300. The molding material 411 may be formed to cover sides of the first semiconductor chip 100, sides of the plurality of second semiconductor chips 200, and sides and the upper surface of the dummy chip 300. Here, according to an example implementation, the sides of the molding material 411 may be aligned with the sides of the carrier substrate CA or the sides of the adhesive material layer GL.

Here, the thickness of a portion of the molding material 411 covering the side of the first semiconductor chip 100 may be thicker than the thickness of a portion of the molding material 411 covering the side of the second semiconductor chip 200. The contents already explained with reference to FIG. 1 to FIG. 4 are omitted.

FIG. 14I is a cross-sectional view illustrating an operation of removing an upper portion of a molding material according to an example implementation.

Referring to FIG. 14I, in order to remove the upper portion of the molding material 411, a CMP process, an etch-back process, or a combination thereof may be used. As the upper portion of the molding material 411 is polished, the upper surface of the molding material 411 and the upper surface of the dummy chip 300 may form the same plane. In the process of removing the upper portion of the molding material 411, a portion of the supportive dummy substrate 310 of the dummy chip 300 may also be removed.

FIG. 14J is a cross-sectional view illustrating an operation of attaching the first chip structure CS1 to the third chip structure CS3 formed on the carrier substrate CA on a second tape TA2 according to an example implementation.

Referring to FIG. 14J, in order for the upper surfaces of the dummy chips 300 of the first chip structure CS1 to the third chip structure CS3 to be in contact with the second tape TA2, the first chip structure CS1 to the third chip structure CS3 may be attached to the second tape TA2.

FIG. 14K is a cross-sectional view illustrating an operation of separating the carrier substrate CA from the first chip structure CS1 to the third chip structure CS3 attached to the second tape TA2 according to an example implementation.

Referring to FIG. 14K, when separating the carrier substrate CA from the first chip structure CS1 to the third chip structure CS3, a portion of the adhesive material layer GL may also be separated together with the carrier substrate CA.

FIG. 14L is a cross-sectional view illustrating an operation of removing the adhesive material layer GL according to an example implementation.

Referring to FIG. 14L, when the adhesive material layer GL is removed, the first connecting pad 151 and the first connecting bump 152 of the first semiconductor chip 100 may be exposed to the outside. Here, a portion of the molding material 411 may also be exposed. The exposed portion of the molding material 411 may be a portion located between the first semiconductor chips 100 of each of the first chip structure CS1 to the third chip structure CS3.

FIG. 14M is a cross-sectional view illustrating an operation of cutting the molding material 411 according to an example implementation.

Referring to FIG. 14M, the molding material 411 may be cut based on the dicing line DL between the first chip structure CS1 and the second chip structure CS2 and the dicing line DL between the second chip structure CS2 and the third chip structure CS3. The cutting may indicate dicing. One of the first chip structure CS1 to the third chip structure CS3 may be located in each area of the molding material 411 that is sectioned by cutting. The dicing line DL may have a gap defined by the second gap G2. The second gap G2 of the dicing line DL may be smaller than the first gap G1 of the scribe lane SL as illustrated in FIG. 14F. After the cutting, the gap between the molding layers 410 covering the first chip structure CS1 to the third chip structure CS3 may be the second gap G2.

In some implementations, when the molding material 411 is cut based on the dicing line DL, the molding layer 410 sectioned based on the dicing line DL may be formed.

FIG. 14N is a cross-sectional view illustrating a semiconductor device according to an example implementation.

Referring to FIG. 14M and FIG. 14N, the semiconductor device 10 according to an example implementation is completed by removing the second tape TA2 attached to the dummy chip 300. As a semiconductor device according to an example implementation, the semiconductor device 10 illustrated in FIG. 14N is the semiconductor device 10 illustrated in FIG. 1 to FIG. 3. The description of the manufacturing process of a semiconductor device is based on the semiconductor device 10 illustrated in FIG. 1 to FIG. 3, but the process for manufacturing the semiconductor devices 10a, 10c, 10d and 10e according to another example implementation is similar.

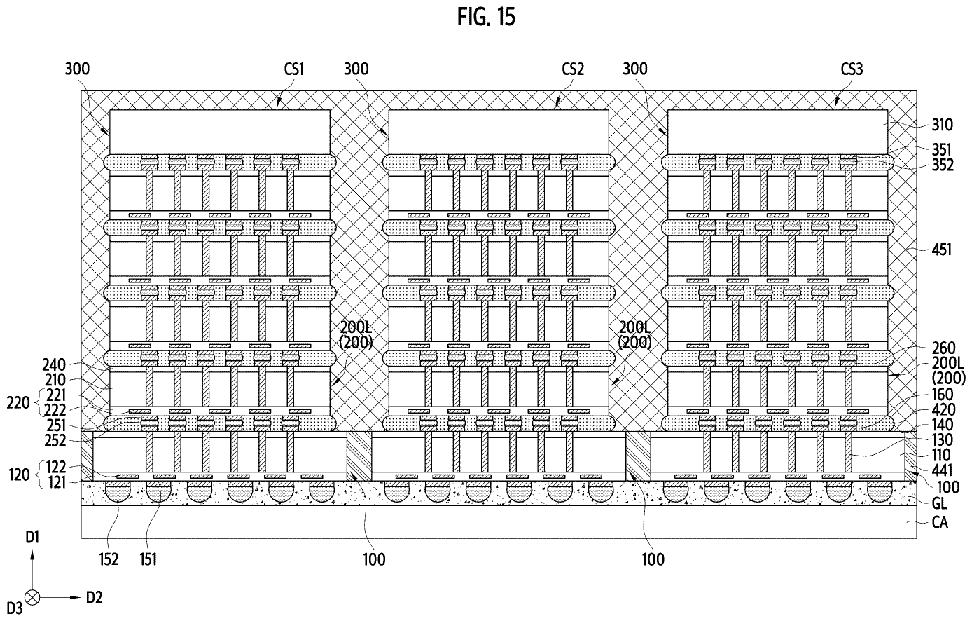

FIG. 15 is a cross-sectional view illustrating an example of a method for manufacturing a semiconductor device.

More specifically, the method for manufacturing the semiconductor device illustrated in FIG. 15 is part of the process for manufacturing the semiconductor device 10b illustrated in FIG. 5. FIG. 15 corresponds to a cross-sectional view for explaining a method for manufacturing a semiconductor device illustrated in FIG. 14H. In other words, the processes for achieving the process illustrated in FIG. 15 are identical to the processes described with reference to FIG. 14A to FIG. 14G. Therefore, the contents already described with reference to FIG. 14A to FIG. 14G are omitted or briefed.

Referring to FIG. 15, a first molding material 441 may be formed to surround the first semiconductor chip 100 on the carrier substrate CA.

In some implementations, the first molding material 441 may be formed to cover the side of the first semiconductor chip 100. In some implementations, the side of the first molding material 441 may be aligned with the side of the carrier substrate CA or the side of the adhesive material layer GL. The upper surface of the first molding material 441 may be coplanar with the upper surface of the first semiconductor chip 100.

After then, a second molding material 451 may be formed on the first molding material 441 to surround the plurality of second semiconductor chips 200 and the dummy chip 300.

In some implementations, the second molding material 451 may be formed to cover sides of the plurality of second semiconductor chips 200 and the dummy chip 300. In some implementations, the sides of the second molding material 451 may be aligned with the sides of the carrier substrate CA, the sides of the adhesive material layer GL, or the sides of the first molding material 441. The upper surfaces of the second molding material 451 may be formed higher than the upper surfaces of the dummy chips 300.

In some implementations, the first molding material 441 and the second molding material 451 may have different thermal expansion coefficients. The first molding material 441 and the second molding material 451 may be made of, for example, the EMC. The first molding material 441 and the second molding material 451 may include the pillars. The pillar may be made of, for example, silica. The pillar may have a size of, for example, one-digit number um to two-digit number um, and may have an average size of about 2 to 10 μm. For example, the first molding material 441 and the second molding material 451 may include a pillar having a mass of about 80% to 90%. In other words, the proportion of the pillar included in the first molding material 441 and the second molding material 451 may be about 80 wt % to 90 wt %.

After then, a series of operations illustrated in FIG. 14I to FIG. 14N may be performed to manufacture the semiconductor device 10b illustrated in FIG. 5. A detailed explanation thereof will be omitted.

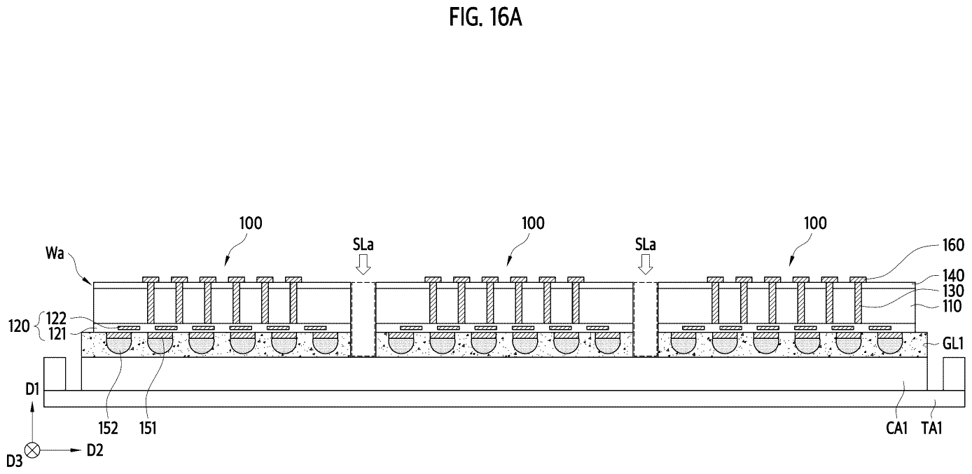

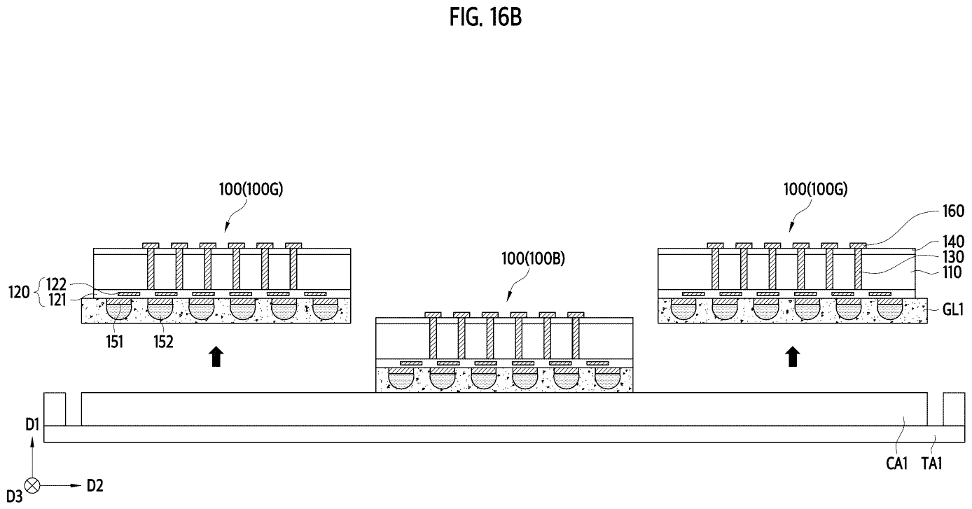

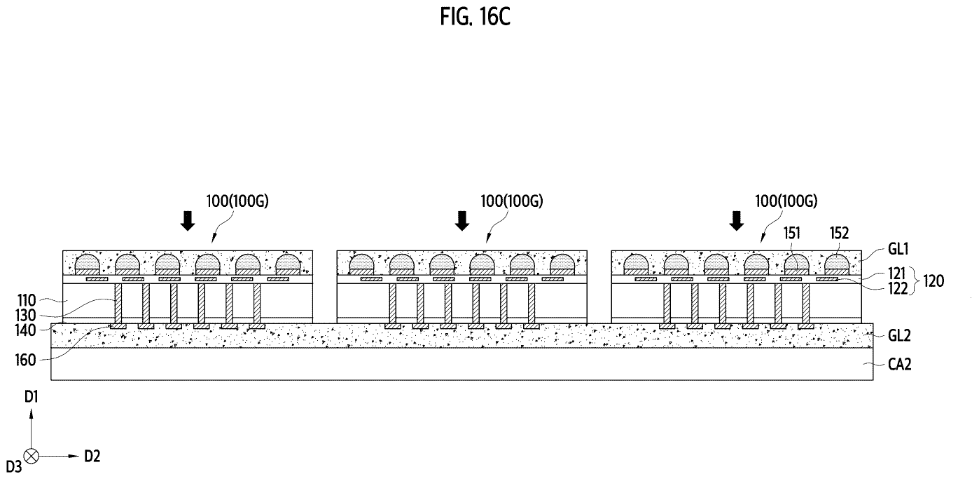

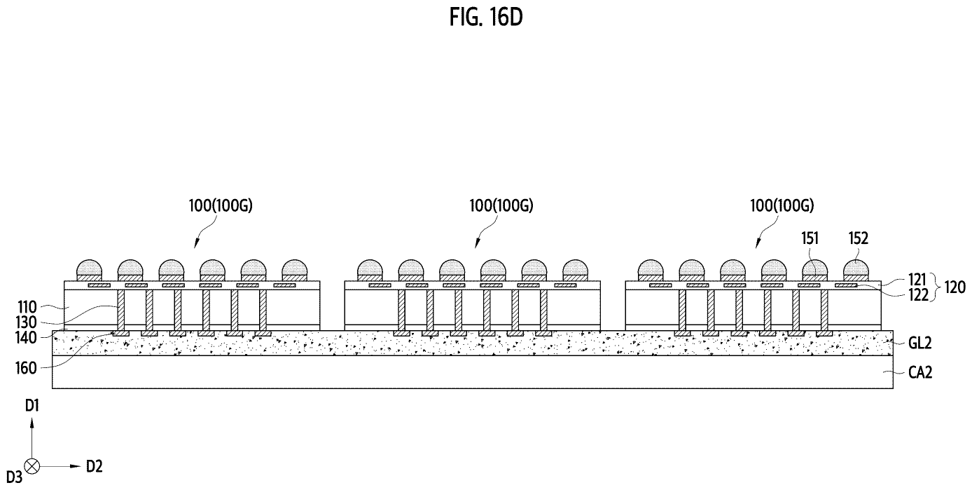

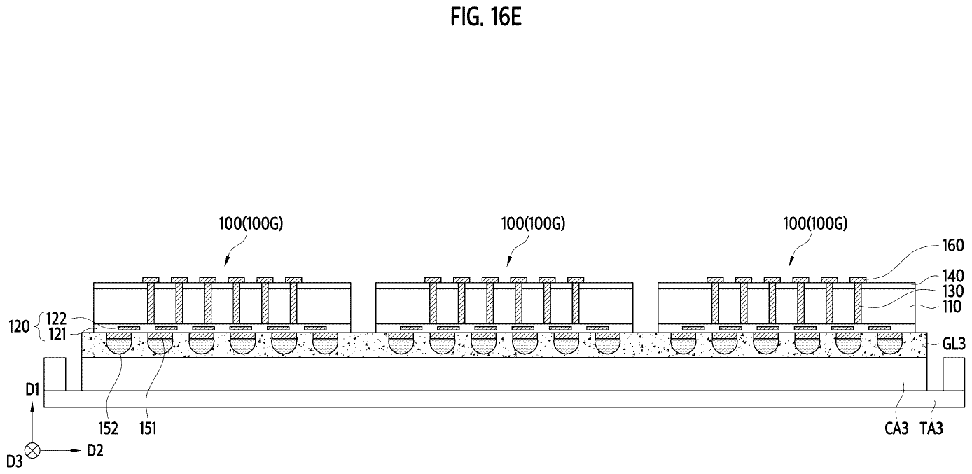

FIGS. 16A, 16B, 16C, 16D, and 16E are cross-sectional views illustrating a process sequence for explaining an example of a method of manufacturing a semiconductor device.

More specifically, the method for manufacturing the semiconductor device illustrated in FIG. 16A to FIG. 16E is part of the process for manufacturing the semiconductor device 10 illustrated in FIG. 1 to FIG. 3. The method for manufacturing the semiconductor device illustrated in FIG. 16A to FIG. 16E is a process for manufacturing the semiconductor device illustrated in FIG. 1 to FIG. 3, and is a manufacturing method distinct from the method of manufacturing the semiconductor device according to the example implementations illustrated with respect to FIG. 14A to FIG. 14N.

FIG. 16A corresponds to a cross-sectional view illustrating a method for manufacturing a semiconductor device illustrated in FIG. 14F. In other words, operations for reaching the process illustrated in FIG. 16A are identical to the operations described with reference to FIG. 14A to FIG. 14E. Therefore, the contents already described with reference to FIG. 14A to FIG. 14E are omitted or briefed.

FIG. 16A is a cross-sectional view illustrating dicing a semiconductor wafer Wa along a scribe lane SLa.

Referring to FIG. 16A, first, a first carrier substrate CA1 on which the semiconductor wafer Wa is mounted may be attached to the first tape TA1. After then, the semiconductor wafer Wa may be diced along the scribe lane SLa. Here, the semiconductor chips 100 in FIG. 16A that are diced along the scribe lane SLa may be separated from each other by the first semiconductor chip 100 that is physically separated from each other.

In some implementations, as the first semiconductor chips 100 are separated from each other through the dicing process, the first semiconductor chips 100 may be picked up from the first carrier substrate CA1.

FIG. 16B is a cross-sectional view illustrating an operation of separating good first semiconductor chips 100G from the first carrier substrate CA1 according to an example implementation.

Referring to FIG. 16B, a test may be performed to evaluate whether there are any defects in the plurality of first semiconductor chips 100 illustrated in FIG. 16A. After the test, the plurality of first semiconductor chips 100 may be classified into a first semiconductor chip 100G of good quality that passed the test, and a first semiconductor chip 100B, which is a defective product that failed the test. The first semiconductor chips 100G of good quality products that passed the test may be separated from the first carrier substrate CA1. The defective first semiconductor chip 100B that fails the test may remain on the first carrier substrate CA1.

FIG. 16C is a cross-sectional view illustrating an operation of attaching the good first semiconductor chips 100G to a second carrier substrate CA2 according to an example implementation.

Referring to FIG. 16C, the second carrier substrate CA2 may be provided having an upper surface on which a second adhesive material layer GL2 is formed. The first semiconductor chips 100G of good quality that passed the test in the FIG. 16B process may be attached to the second carrier substrate CA2. Here, the first semiconductor chips 100G of good quality may be attached to the second carrier substrate CA2 such that the first back side pads 160 faces the second adhesive material layer GL2. The first back side pads 160 may be bonded by contacting the second adhesive material layer GL2. The first connecting bumps 152 and a first adhesive material layer GL1 of the first semiconductor chips 100G of the good quality may be positioned so as to face the first direction D1. The first semiconductor chips 100G of good quality attached to the second carrier substrate CA2 may be arranged spaced apart from each other while maintaining a certain gap.

FIG. 16D is a cross-sectional view illustrating an operation of removing the first adhesive material layer GLI according to an example implementation.

Referring to FIG. 16D, the first adhesive material layer GL1 may be removed to expose the first connecting bumps 152 of the first semiconductor chips 100G of the good quality. In some implementations, as the first adhesive material layer GL1 is removed, the first connecting pad 151 may be exposed along with the first connecting bump 152.

FIG. 16E is a cross-sectional view illustrating an operation of attaching the first semiconductor chips 100 to a third carrier substrate CA3 in order for the first connecting bumps 152 to face the third carrier substrate CA3, according to an example implementation.

Referring to FIG. 16E, the third carrier substrate CA3 attached to a third tape TA3 may be provided. A third adhesive material layer GL3 may be formed on the third carrier substrate CA3. The lower surface of the first semiconductor chip 100 may be attached to the third adhesive material layer GL3. The first connecting bump 152 and the first connecting pad 151 may be embedded within the third adhesive material layer GL3. The first back side pads 160 of the first semiconductor chip 100G of good quality mounted on the third carrier substrate CA3 may be arranged to face the first direction D1.

Through a series of operations illustrated in FIG. 16A to FIG. 16E, a series of operations performed after FIG. 16E may be performed on the first semiconductor chips 100G of good quality that passed the test. In other words, the operation of stacking the second semiconductor chips 200 and forming the molding layer 410 may be performed on the first semiconductor chips 100G of good quality that passed the test. Subsequent processes for defective semiconductor chips that fail testing may be prevented, and thus a method for manufacturing semiconductor devices with improved yield may be implemented.

After then, a series of operations illustrated in FIG. 14G to FIG. 14N may be performed to manufacture the semiconductor device 10 illustrated in FIG. 1 to FIG. 3. The description of the manufacturing process of the present semiconductor device is based on the semiconductor device 10 illustrated in FIG. 1 to FIG. 3 as an example, but operations for manufacturing a semiconductor device (semiconductor devices 10a, 10b, 10c, 10d, 10e and 20) according to another example implementation is similar.

FIGS. 17A, 17B, 17C, and 17D are cross-sectional views illustrating a process sequence for explaining an example of a method of manufacturing a semiconductor device.

More specifically, the method for manufacturing the semiconductor device illustrated in FIG. 17A to FIG. 17D is part of a process for manufacturing the semiconductor device 20 illustrated in FIG. 11 and FIG. 12. FIG. 17A corresponds to a cross-sectional view illustrating a method for manufacturing a semiconductor device illustrated in FIG. 14E. In other words, the operations to achieve the process illustrated in FIG. 17e are identical to the operations described with reference to FIG. 14A to FIG. 14D. Therefore, the contents already explained with reference to FIG. 14A to FIG. 14D are omitted or simplified below.

FIG. 17A is a cross-sectional view illustrating an operation of having the carrier substrate CA having the plurality of first semiconductor chips 500 mounted thereon according to an example implementation.

Referring to FIG. 17A, the first semiconductor chips 500 having the upper chip connecting pads 561 with exposed upper surfaces may be mounted on the carrier substrate CA. The components included in the first semiconductor chip 500 are identical to those mentioned with reference to FIG. 11 and FIG. 12, and thus detailed descriptions thereon will be omitted.

In some implementations, the plurality of upper chip connecting pads 561 and the upper chip connecting insulation layer 551 are formed on the upper surface of the first semiconductor chip 500. The plurality of upper chip connecting pads 561 may be arranged on the upper surfaces, or, the inactive surfaces, of the first substrate 510. The plurality of upper chip connecting pads 561 may be arranged on the upper surfaces of the first substrates 510 to be connected to the plurality of first through electrodes 530. The upper chip connecting insulation layer 551 may be formed to surround sides of the plurality of upper chip connecting pads 561 on the upper surface, or, the inactive surface, of the first substrate 510. The upper chip connecting insulation layer 551 may cover the upper surface of the first substrate 510 and the sides of the plurality of upper chip connecting pads 561, while exposing the upper surfaces of the plurality of upper chip connecting pads 561.

In some implementations, the plurality of upper chip connecting pads 561 may be arranged corresponding to the plurality of first through electrodes 530. A lower portion of the plurality of first through electrodes 530 may be connected to the first interconnection structure 520, and the upper portion of the plurality of first through electrodes 530 may be connected to the upper chip connecting pad 561.

In some implementations, the first semiconductor chips 500 mounted on the carrier substrate CA may be separated from each other. As illustrated in FIG. 14F, the first semiconductor chips 500 mounted on the carrier substrate CA may be separated from each other by dicing.

FIG. 17B is a cross-sectional view illustrating an operation of stacking the second semiconductor chips 600 (specifically, the bottom second semiconductor chips 600L) on the first semiconductor chips 500 according to an example implementation.

Referring to FIG. 17B, the plurality of upper chip connecting pads 561 and the upper chip connecting insulation layer 551 are also formed on the upper surface of the second substrate 610. The plurality of upper chip connecting pads 561 may be arranged on the upper surface, or, the inactive surface, of the second substrate 610. The plurality of upper chip connecting pads 561 may be arranged on the upper surface of the second substrate 610 to be connected to the plurality of second through electrodes 630. The upper chip connecting insulation layer 551 may be formed to surround sides of the plurality of upper chip connecting pads 561 on the upper surface, or, the inactive surface, of the second substrate 610. The upper chip connecting insulation layer 551 may cover the upper surface of the second substrate 610 and the sides of the plurality of upper chip connecting pads 561, while exposing the upper surfaces of the plurality of upper chip connecting pads 561.

In some implementations, the plurality of lower chip connecting pads 562 and the lower chip connecting insulation layer 552 are formed on the lower surface of the second substrate 610. The plurality of lower chip connecting pads 562 may be arranged on the lower surface of the second substrate 610, or, the lower surface of the second interconnection structure 620. The plurality of lower chip connecting pads 562 may be arranged on the lower surface of the second substrate 610 to be connected to the second interconnection pattern 622 and/or the second interconnection via 623. The lower chip connecting insulation layer 552 may be formed to surround sides of the plurality of lower chip connecting pads 562 on the lower surface of the second substrate 610. The lower chip connecting insulation layer 552 may cover the lower surface of the second substrate 610 and the sides of the plurality of lower chip connecting pads 562, while exposing the lower surfaces of the plurality of lower chip connecting pads 562.

In some implementations, on the first semiconductor chip 500, the bottom second semiconductor chip 600L is positioned. The bottom second semiconductor chip 600L may be positioned on the first semiconductor chip 500 such that the second interconnection structure 620 faces the first semiconductor chip 500. The second semiconductor chip 600 may be positioned on the first semiconductor chip 500, in order for the plurality of lower chip connecting pads 562 formed on the lower surface of the second semiconductor chip 600 to correspond to the plurality of upper chip connecting pads 561 formed on the upper surface of the first semiconductor chip 500. For example, each of the plurality of upper chip connecting pads 561 and the plurality of lower chip connecting pads 562 may be made of a material containing Cu.

FIG. 17C is a cross-sectional view illustrating an operation of directly bonding the upper chip connecting pad 561 and the lower chip connecting pad 562 and directly bonding the upper chip connecting insulation layer 551 and the lower chip connecting insulation layer 552 according to an example implementation.

Referring to FIG. 17C together with FIG. 17B, by heating and/or applying the pressure in the process of positioning the second semiconductor chip 600 on the first semiconductor chip 500, the plurality of upper chip connecting pads 561 and the plurality of lower chip connecting pads 562 may be connected, and the upper chip connecting insulation layer 551 and the lower chip connecting insulation layer 552 may be bonded. In some implementations, the plurality of upper chip connecting pads 561 and the plurality of lower chip connecting pads 562 may be joined by covalent bonding, and the upper chip connecting insulation layer 551 and the lower chip connecting insulation layer 552 may be joined by covalent bonding. For example, in the process of positioning the second semiconductor chip 600 on the first semiconductor chip 500, heat of the first temperature may be applied.

After then, by applying heat at a second temperature higher than the first temperature, the plurality of upper chip connecting pads 561 and the plurality of lower chip connecting pads 562 that correspond to each other are combined to form the plurality of chip connecting pads 560, and the chip connecting insulation layer 550 is formed by combining the upper chip connecting insulation layer 551 and the lower chip connecting insulation layer 552. The plurality of lower chip connecting pads 562 and the plurality of upper chip connecting pads 561 corresponding to each other may be expanded by heat and come into contact with each other, and the plurality of chip connecting pads 560 may be formed by diffusion bonding through diffusion of metal atoms.

FIG. 17D is a cross-sectional view illustrating an operation of stacking the plurality of second semiconductor chips 600 and the dummy chip 700 according to an example implementation.

In some implementations, the plurality of second semiconductor chips 600 may be stacked on the bottom second semiconductor chips 600L by repeating the series of processes illustrated in FIG. 17B and FIG. 17C. When the stacking of the plurality of second semiconductor chips 600 is completed, the dummy chips 700 may be stacked on the top second semiconductor chips 600H. Here, by forming the supportive connection insulation layers 720 between the top second semiconductor chips 600H and the supportive dummy substrates 310 using a method similar to what is described with respect to FIG. 17B and FIG. 17C, the supportive dummy substrates 710 may be attached on the top second semiconductor chips 600H. For example, the supportive connection insulation layer 720 may be an insulation layer in which the upper chip connecting insulation layer 551 of the top second semiconductor chip 600H and the insulation layer attached below the supportive dummy substrate 710 are bonded to each other.

After then, a series of operations illustrated in FIG. 14H to FIG. 14N may be performed to manufacture the semiconductor device 20 illustrated in FIG. 11 and FIG. 12.

In some implementations, a semiconductor device may be manufactured by stacking a plurality of memory chips on a semiconductor chip substrate that constitutes a buffer chip. Here, before stacking memory chips, the buffer chips may be physically separated through the dicing process on the semiconductor chip substrate. By physically separating the buffer chips, the stress in each gap between buffer chips may be reduced even when memory chips are stacked in multiple steps on each buffer chip.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

As described above, example implementations are disclosed with respect to the drawings in the present disclosure. In the present disclosure, the example implementations are described using specific terms, but the terms are used solely for the purpose of explaining the technical ideas of the present disclosure and are not intended to limit the meaning or scope of the present disclosure as set forth in the claims. Therefore, those skilled in the art will understand that various modifications and equivalent example implementations are possible from this.

1. A semiconductor device comprising:
a first semiconductor chip comprising a first substrate and a first through electrode, the first through electrode extending into the first substrate;
a plurality of second semiconductor chips that comprise a second substrate and a second through electrode sequentially stacked in a first direction intersecting a surface of the first semiconductor chip, the second substrate being disposed in the first direction, and the second through electrode extending into the second substrate; and
a molding layer surrounding the first semiconductor chip and the plurality of second semiconductor chips,
wherein a first thickness of a first part of the molding layer is different from a second thickness of a second part of the molding layer, the first part of the molding layer contacting a side of the first semiconductor chip, and the second part of the molding layer contacting a side of the plurality of second semiconductor chips.

2. The semiconductor device of claim 1, wherein a distance between a first outer side and a second outer side of the molding layer is greater than a width of the first semiconductor chip in a second direction, the first outer side and the second outer side being spaced apart in the second direction, and the second direction intersecting the first direction.

3. The semiconductor device of claim 1, wherein the first thickness of the first part is smaller than the second thickness of the second part.

4. The semiconductor device of claim 1, wherein the first thickness of the first part of the molding layer is within a range of 30 μm to 300 μm.

5. The semiconductor device of claim 1, wherein the first semiconductor chip is a buffer chip,
wherein the plurality of second semiconductor chips are a plurality of memory chips, and
wherein the first semiconductor chip is configured to control the plurality of second semiconductor chips.

6. The semiconductor device of claim 1, wherein the side of the first semiconductor chip is misaligned with a side of the molding layer.

7. The semiconductor device of claim 1, wherein the side of the first semiconductor chip includes a first side of the first semiconductor chip or a second side of the first semiconductor chip, and
wherein a thickness of a first portion of the molding layer is equal to a thickness of a second portion of the molding layer, the first portion of the molding layer covering the first side of the first semiconductor chip parallel to the first direction, the second portion of the molding layer covering the second side of the first semiconductor chip, and the second side intersecting the first side.

8. The semiconductor device of claim 1, wherein the side of the first semiconductor chip includes a first side of the first semiconductor chip or a second side of the first semiconductor chip, and
wherein a thickness of a first portion of the molding layer is different from a thickness of a second portion of the molding layer, the first portion of the molding layer covering the first side of the first semiconductor chip parallel to the first direction, the second portion of the molding layer covering the second side of the first semiconductor chip, and the second side intersecting the first side.

9. The semiconductor device of claim 1, wherein the first semiconductor chip comprises four sides that are parallel to the first direction, and parts of the molding layer contact the four sides have different thicknesses from each other.

10. The semiconductor device of claim 1, comprising an under-filling layer that is interposed between the first semiconductor chip and a bottom second semiconductor chip among the plurality of second semiconductor chips,
wherein the molding layer covers the under-filling layer.

11. The semiconductor device of claim 10, wherein a thickness of a portion of the molding layer that contacts the under-filling layer is within a range of 30 μm to 300 μm.

12. The semiconductor device of claim 1, wherein a thickness of the first part in a second direction is greater than a distance between the side of the first semiconductor chip and the side of the plurality of second semiconductor chips in the second direction, the second direction intersecting the first direction.

13. A semiconductor device comprising:
a package substrate; and
a memory chip structure comprising a plurality of chips on the package substrate,
wherein the plurality of chips comprise:
a buffer chip comprising a first substrate and a first through electrode, the first through electrode extending into the first substrate, and the buffer chip being at a bottom among the plurality of chips;
a plurality of memory chips comprising a second substrate and a second through electrode, the second substrate being disposed along a first direction intersecting a surface of the buffer chip, the second through electrode extending into the second substrate, and the plurality of memory chips being sequentially stacked in the first direction; and
a first molding layer surrounding the buffer chip,
wherein a length of outer circumference of the first molding layer is longer than a length of outer circumference of the buffer chip.

14. The semiconductor device of claim 13, comprising a second molding layer surrounding the plurality of memory chips,
wherein an outer side of the first molding layer intersecting the first direction and an outer side of the second molding layer intersecting the first direction are coplanar with each other.

15. The semiconductor device of claim 14, wherein first thermal expansion coefficient of the first molding layer is different from second thermal expansion coefficient of the second molding layer.

16. The semiconductor device of claim 13, wherein a width of the buffer chip in a second direction intersecting the first direction is greater than a width of each memory chip of the plurality of memory chips in the second direction.

17. The semiconductor device of claim 13, comprising:
a lower bonding pad disposed between a pair of neighboring memory chips among the plurality of memory chips;
an upper bonding pad facing the lower bonding pad in the first direction and being directly bonded with the lower bonding pad;
a lower bonding insulation layer surrounding the lower bonding pad; and
an upper bonding insulation layer surrounding the upper bonding pad and being directly bonded with the lower bonding insulating layer.

18. The semiconductor device of claim 13, comprising:
an interposer disposed between the package substrate and the memory chip structure; and
a logic chip structure that is on the interposer and spaced apart from the memory chip structure in a second direction intersecting the first direction.

19. The semiconductor device of claim 13, comprising a dummy chip positioned on a top memory chip among the plurality of memory chips,
wherein the length of outer circumference of the first molding layer is longer than a length of outer circumference of the dummy chip.

20. A semiconductor device comprising a buffer chip and a plurality of memory chips that are sequentially stacked in a first direction intersecting a surface of the buffer chip,
wherein the buffer chip comprises a first substrate having an inactive surface, a first through electrode extending into the first substrate, a first interconnection structure on a lower surface of the first substrate, and a first connecting bump being connected with the first interconnection structure,
wherein each memory chip of the plurality of memory chips comprises a second substrate having a width smaller than a width of the first substrate and having an active surface facing the inactive surface of the first substrate, a second through electrode extending into the second substrate, a second interconnection structure on a lower surface of the second substrate, and a second connecting bump being connected with the second interconnection structure,
the semiconductor device comprising:
an under-filling layer interposing between each memory chip of the plurality of memory chips to surround the second connecting bump; and
a molding layer surrounding the buffer chip, the plurality of memory chips, and the under-filling layer, the molding layer comprising a bottom surface being coplanar with a lower surface of the buffer chip, and
wherein a first thickness of a first part of the molding layer surrounding the first substrate is thinner than a second thickness of a second part of the molding layer surrounding the second substrate.
